(19) United States
(12) Patent Application Publication
(10) Pub. No.: US 2021/0296436 A1
(43) Pub. Date: Sep. 23, 2021

(54) Electronic Device Including an Active Region

(71) Applicant: Semiconductor Components Industries, LLC, Phoenix, AZ (US)

(72) Inventor: Gary H. Loechelt, Tempe, AZ (US)

(73) Assignee: Semiconductor Components Industries, LLC, Phoenix, AZ (US)

(21) Appl. No.: 16/827,425

(22) Filed: Mar. 23, 2020

(51) Int. Cl. H01L 29/06

(52) U.S. Cl. CPC H01L 29/0634

(57) ABSTRACT

An electronic device can include a die that has an active region and a termination region. Pillars within an active region near the termination region can help reduce an electrical field near a boundary of the active and termination regions adjacent to a primary surface of a substrate. In an embodiment, the reduced electrical field may be achieved by having reduced net charge within pillars of the active region near the termination region, as opposed to pillars near the center of the active region. In another embodiment, the reduced electrical field can be achieved by partially doping pillars within the active region that are closer to the termination region or by at least partly counter doping such pillars.

### FIELD OF THE DISCLOSURE

The present disclosure relates to electronic devices including active regions and processes of forming such electronic devices.

### RELATED ART

Power transistors can operate at voltages of 100 V and higher. A peripheral region of a die may be maintained at the drain voltage. An active region of the electronic device can include contacts, a source terminal and a gate terminal that are at substantially lower voltages than the drain voltage. A termination region is disposed between the peripheral region and the active region. The design of cells within a center of the active region and within another part of the active region adjacent to the termination region is substantially the same.

A power transistor can include cells that have a superjunction design. High voltage breakdown in the active region is achieved by having a superjunction design and can include an array of alternating n-type pillars and p-type pillars that form a charge-balanced structure. Careful attention to the design is needed to avoid charge imbalance. Ideally, the breakdown voltage associated with the termination region should be higher than the breakdown voltage within the active region of the device. Further improvement of the breakdown voltage associated with the termination structure is desired.

### BRIEF DESCRIPTION OF THE DRAWINGS

Embodiments are illustrated by way of example and are not limited in the accompanying figures.

FIG. 1 includes an illustration of a top view of a die including active, termination, and peripheral regions.

FIG. 2 includes an illustration of a cross-sectional view of a portion of a workpiece including a substrate of the die.

FIG. 3 includes a top view of the workpiece and openings for p-type doping and n-type doping with respect to trenches within the active region.

FIG. 4 includes a cross-sectional view of the workpiece after doping using the patterns illustrated in FIG. 3 and defining trenches and before a dopant drive operation.

FIG. 5 includes a cross-section view of the workpiece of FIG. 4 after a dopant drive operation.

FIG. 6 includes a top view of the workpiece and openings for p-type doping and n-type doping with respect to trenches within the active region in accordance with an alternative embodiment.

FIG. 7 includes a top view of the workpiece and openings for p-type doping with respect to trenches within the active region.

FIG. 8 includes a top view of the workpiece and openings for n-type doping with respect to trenches within the active region.

FIG. 9 includes a top view of a composite of FIGS. 7 and 8 of the workpiece and openings for p-type doping and n-type doping with respect to trenches within the active region.

FIG. 10 includes a cross-sectional view of the workpiece after doping using the patterns illustrated in FIG. 9 and defining trenches and before a dopant drive operation.

FIG. 11 includes a cross-section view of the workpiece of FIG. 10 after a dopant drive operation.

FIG. 12 includes a top view of the workpiece and openings for n-type doping with respect to trenches within the active region in accordance with an alternative embodiment.

FIG. 13 includes a top view of a composite of FIGS. 7 and 12 of the workpiece and openings for p-type doping and n-type doping with respect to trenches within the active region.

FIG. 14 includes a top view of the workpiece and openings for p-type doping with respect to trenches within the active region.

FIG. 15 includes a top view of a composite of FIGS. 8 and 14 of the workpiece and openings for n-type doping and p-type doping with respect to trenches within the active region.

FIG. 16 includes a cross-sectional view of the workpiece after doping using the patterns illustrated in FIG. 15 and defining trenches and before a dopant drive operation.

FIG. 17 includes a cross-section view of the workpiece of FIG. 16 after a dopant drive operation.

FIG. 18 includes a top view of the workpiece and openings for p-type doping with respect to trenches within the active region in accordance with an alternative embodiment.

FIG. 19 includes a top view of a composite of FIGS. 12 and 18 of the workpiece and openings for n-type doping and p-type doping with respect to trenches within the active region.

FIG. 20 includes a top view of the workpiece and openings for n-type doping with respect to trenches within the active region.

FIG. 21 includes a top view of a composite of FIGS. 7 and 20 and openings for n-type doping and p-type doping with respect to trenches within the active region.

FIG. 22 includes a cross-sectional view of the workpiece after doping using the patterns illustrated in FIG. 21 and defining trenches and before a dopant drive operation.

FIG. 23 includes a cross-section view of the workpiece of FIG. 22 after a dopant drive operation.

FIG. 24 includes a top view of the workpiece and openings for n-type doping with respect to trenches within the active region in accordance with an alternative embodiment.

FIG. 25 includes a top view of a composite of FIGS. 7 and 24 of the workpiece and openings for p-type doping and n-type doping with respect to trenches within the active region.

FIG. 26 includes a cross-sectional view of the workpiece of FIG. 23 after forming a semiconductor layer, recessing the semiconductor layer within the trenches, and forming an insulating layer.

FIG. 27 includes a cross-sectional view of the workpiece of FIG. 26 after forming p-well regions, a gate dielectric layer, gate electrodes, and source regions.

FIG. 28 includes a cross-sectional view of the workpiece of FIG. 27 after forming an insulating layer within the trenches and over the pillars, patterning the insulating layer to define contact openings, and forming body contact regions.

FIG. 29 includes a cross-sectional view of the workpiece of FIG. 28 after forming a substantially completed electronic device.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application.

A border between a more heavily doped region or layer and an immediately adjacent and more lightly doped region or layer of the same conductivity type is where the dopant concentration of the more lightly doped region or layer is 10% higher than the difference between the peak dopant concentration of the more heavily doped region and the average dopant concentration of such more lightly doped region or layer.

The term “high voltage” is intended to mean a voltage of at least 110 V.

Unless explicitly stated to the contrary, the terms “horizontal,” “lateral,” and their variants are in a direction parallel to a primary surface of a substrate or semiconductor layer, and the terms “vertical” and its variants are in a directions perpendicular to a primary surface of a substrate or a semiconductor layer.

The term “voltage rating,” with reference to an electronic device, means a nominal voltage that the electronic device is designed to operate. For example, a transistor with a voltage rating of 50 V is designed for a 50 V difference between drain and source regions or electrodes or collector and emitter regions or electrodes when the transistor is in an off-state. The transistor may be able to withstand a higher voltage, such as 60 V or 70 V, for a limited duration, such as during and shortly after a switching operation, without significantly permanently damaging the transistor.

The terms “on,” “overlying,” and “over” may be used to indicate that two or more elements are in direct physical contact with each other. However, “over” may also mean that two or more elements are not in direct contact with each other. For example, “over” may mean that one element is above another element, but the elements do not contact each other and may have another element or elements in between the two elements.

The terms “comprises,” “comprising,” “includes,” “including,” “has,” “having,” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read such that the plurals include one or at least one and the singular also includes the plural, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Thus, differences of up to ten percent (10%) (and up to twenty percent (20%) for semiconductor doping concentrations) for the value are reasonable differences from the ideal goal of exactly as described. When values of a parameter are significantly different, such values are more than 10% different (and more than 20% different for semiconductor doping concentrations). When values of a parameter are different (e.g., less than, greater than, a numerical difference between values, or the like), without being modified by significantly or insignificantly, any difference beyond manufacturing tolerances for commercial production are considered different.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

An electronic device can include a die that has an active region and a termination region. Pillars within an active region near the termination region can help reduce an electrical field near a boundary of the active and termination regions near a primary surface of a substrate. The reduced electrical field may be achieved by having reduced net charge within pillars of the active region near the termination region, as opposed to pillars near the center of the active region. The reduced electrical field may be achieved by doping pillars within the active region that are closer to the termination region with part, and not all, of a full dose used to dope corresponding interior pillars, by at least partly counter doping such pillars closer to the termination region, or a combination of partial doses and counter doping. Many different designs can be used. The concepts as described herein are well suited for electronic devices that have a voltage rating in a range from 200 V to 1200 V. The concepts can be extended to electronic devices that have voltage ratings outside the preceding voltage range. The designs can be integrated into an existing process flow without needing to add any further steps.

In an aspect, an electronic device can include an active region including an array of pillars. The array of pillars can include a first pillar having a first net charge of a first charge type, a second pillar having a second net charge of a second net charge type opposite the first charge type, and interior pillars including alternating odd-numbered pillars having third net charges of the first charge type and even-numbered pillars having fourth net charges of the second charge type. The second pillar is disposed between the first pillar and the interior pillars, and an absolute value of the first net charge or an absolute value of the second net charge is less than an absolute value of each of the third net charges.

In another aspect, an electronic device can include an active region including an array of pillars that include a first pillar, a second pillar, and a third pillar. The first pillar can include a first doped region extending along a majority of a first height of the first pillar, wherein the first doped region includes a first dopant at a first average dopant concentration. The second pillar can include a second doped region extending along a majority of a second height of the second pillar, wherein the second doped region includes a second dopant at a second average dopant concentration. The third pillar can include a third doped region extending along a majority of a third height of the third pillar, wherein the third doped region includes a third dopant having a first conductivity type, the third dopant is at a third average dopant concentration. The second pillar is disposed between the first pillar and the third pillar. The third average dopant concentration can be greater than the first average dopant concentration or the second average dopant concentration.

In a further aspect, an electronic device can include an active region including an array of pillars and an insulating layer between and adjacent pillars within the array of pillars. The array of pillars can include an alternating pattern of p-type pillars having acceptor type dopant species and n-type pillars having donor type dopant species. A negative charge is associated with the acceptor type dopant species of the p-type pillars, a positive charge is associated with the donor type dopant species of the n-type pillars and the insulating layer, and an absolute value of a net charge of the active region is no more than 5% of the negative charge.

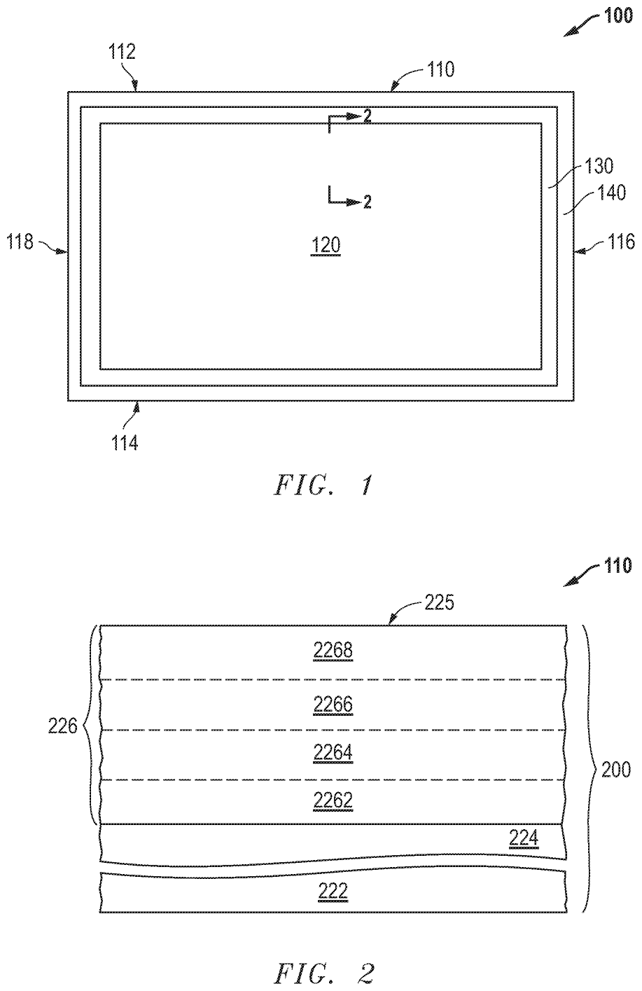

FIG. 1 includes an illustration of a top view of an electronic device 100. The electronic device 100 can be in the form of a die 110 that has sides 112, 114, 116, and 118, where the side 112 is opposite the side 114, and the side 116 is opposite the side 118. The die 110 includes an active region 120 that is surrounded by a termination region 130 that is surrounded by a peripheral region 140. Interconnects (not illustrated in FIG. 1) along the top side of the active regions 120 may be made to the source regions and the gate electrodes and, if present within the die 110, a gate driver and a circuit associated with the gate driver. The voltage for such interconnects may be at the source voltage or may be at a voltage no higher than 10 V above the source voltage. The peripheral region 140 may be electrically connected to backside drain metallization that may be at the drain voltage. Thus, the peripheral region 140 can be a voltage of at least 110 V higher than the source voltage. The concepts as described herein are well suited for a transistor designed for a drain-to-source voltage in a range from 200 V to 1200 V. The termination region 130 helps to provide an electrical field to have a sufficiently high breakdown voltage.

The inventor has discovered that the design of the active region 120 can be modified to change an electrical field near the boundary between the active region 120 and the termination region 130. The design can allow voltage breakdown to occur between the drain and source of cells within the active region 120 before breakdown occurs via the termination region 130. Within the active region 120, net charge, dopant concentration, or both may be different in pillars closer to the termination region 130 as compared to the pillars farther from the termination region 130. The new structures can be achieved by modifying existing masks or other patterns when performing a doping operation and does not require any additional step.

The active region 120 can include hundreds or thousands of pillars that are configured as superjunction structures. As will become apparent to skilled artisan after reading this specification, the figures are simplified to improve understanding of the concepts described herein. In many of the figures, ten trenches and nine pillars are illustrated. In practice, many more trenches and pillars are present within the active region 120. After reading this specification in its entirety, skilled artisans will be able to determine the number of trenches and pillars for a particular application.

Excluding the pillars within the active region 120 that are close to the termination region 130, the interior of the active region 120 has alternating n-type pillars and p-type pillars. The designs described herein modify net charge or doping of pillars within the active region 120 near the termination region 130 while keeping charge substantially balanced or to an acceptably low amount of charge imbalance, such as no greater than 5%, as determined by absolute value of the net charge of the active region 120 divided by the sum of the absolute values of charges within the active region 120, times 100%. For example, in arbitrary units (a.u.), the active region 120 can have negative charge of −102 a.u. (for example, due to p-type doped pillars) and a positive charge of +98 a.u. (for example, due to n-type doped pillars). In this example, the active region has a net charge of −4 a.u. and thus, the absolute value of the net charge is 4 a.u. The sum of the absolute values of the negative and positive charges is |−102 a.u.|+|+98 a.u.|, or 200 a.u. Therefore, the charge imbalance is (4 a.u./200 a.u.)×100%, or 2%.

As described in more detail below, pillars within the active region 120 that are closest to the termination region 130 are referred to herein as the outermost pillars, and pillars next to the outermost pillars are referred to herein as penultimate pillars. Pillars that are farther from the termination region 130 are referred to as interior pillars.

The outermost pillars or the penultimate pillars can have no net charge or a net charge that is half the positive charge or half the negative charge of the interior pillars. The half net charge may be achieved by a dopant concentration that is half of the dopant concentration of the corresponding p-type or n-type interior pillars or may be achieved by having the same dopant concentration as the corresponding p-type or n-type interior pillars and counter doping the outermost or penultimate pillar with a dopant having the opposite conductivity type at a dopant concentration that is approximately half of other interior pillars of the opposite conductivity type. Hence, charge, average dopant concentration, and dose can be expressed as a fractional amount as compared to the charge, average dopant concentration, and dose of interior pillars of the same charge or conductivity type (for average dopant concentration and dose).

In an example, an outermost pillar may have a p-type (electron acceptor-type) dopant at an average dopant concentration that is half of a p-type average dopant concentration of a p-type interior pillar. Alternatively, the outermost pillar may have (1) a p-type dopant at substantially the same average dopant concentration as the p-type interior pillar, and (2) an n-type (electron donor-type) dopant at an average dopant concentration that is half of an n-type average dopant concentration of an n-type interior pillar. In such alternative embodiment, the n-type dopant partly, but does not completely, counter dopes the p-type dopant within the outermost pillar. Other embodiments can be used and will be described later in this specification.

In the embodiments illustrated in the figures, the active region 120 is illustrated with ten trenches for simplicity. In practice, the number of trenches may be significantly different and vary depending on the drain current desired for the high voltage transistor being formed. After reading this specification, skilled artisans will be able to determine the number of pillars and trenches and their dimensions for the needs or desires for a particular application. Except as otherwise explicitly noted, cross-sectional views of the electronic device are along sectioning line 2-2 in FIG. 1.

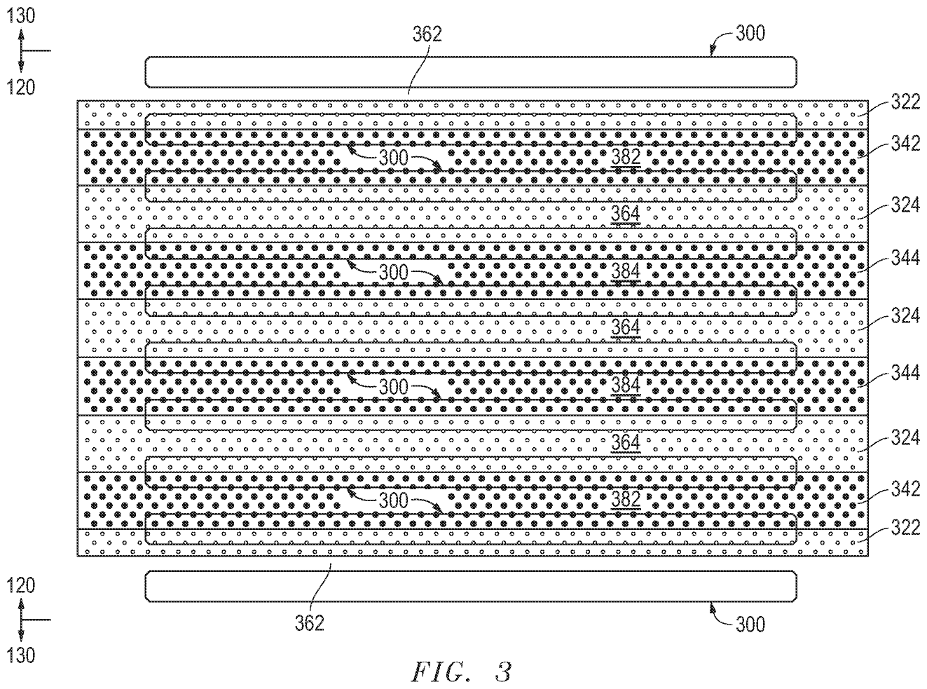

FIG. 2 includes a portion of the die 110 that includes a substrate 200 including a semiconductor base material 222, a lower semiconductor layer 224, and an upper semiconductor layer 226 having a primary surface 225. Each of the semiconductor base material 222, the lower semiconductor layer 224, and the upper semiconductor layer 226 can be monocrystalline and include a semiconductor base material that includes at least one Group 14 element and can include Si, Ge, SiC, SiGe, or the like. In an embodiment, the semiconductor base material 222 can be in the form of a semiconductor wafer. The lower semiconductor layer 224 can be epitaxially grown from the semiconductor base material 222, and the upper semiconductor layer 226 can be epitaxially grown from the lower semiconductor layer 224.

The semiconductor base material 222 can be n-type doped or p-type doped and have a dopant concentration of at least 1×10¹⁸ atoms/cm³. The lower semiconductor layer 224 can have the same conductivity type as the semiconductor base material 222 and a dopant concentration lower than the semiconductor base material 222. In an embodiment, the lower semiconductor layer 224 can have a dopant concentration of at most 5×10¹⁷ atoms/cm³, and in a particular embodiment, is at most 1×10¹⁷ atoms/cm³. The lower semiconductor layer 224 can have a dopant concentration greater than 1×10¹⁵ atoms/cm³. As originally formed, the upper semiconductor layer 226 can be undoped or more lightly doped as compared to the lower semiconductor layer 224. Dopant concentrations, doses, and doping techniques regarding the upper semiconductor layer 226 are described later in this specification.

The thicknesses of the lower semiconductor layer 224 and the upper semiconductor layer 226 can depend on the voltage rating of the transistor. Drift regions for the transistor structures being formed can include a combination of the lower semiconductor layer 224 and n-type pillars that are formed within the upper semiconductor layer 226. In an embodiment, the thickness of the lower semiconductor layer 224 can be in a range from 2 microns to 20 microns. In another embodiment, the thickness of the upper semiconductor layer 226 can be in a range from 3 microns to 95 microns. For a transistor having a voltage rating of 600 V, the upper semiconductor layer 226 can have a thickness in a range from 40 microns to 60 microns. For a lower voltage rating, the upper semiconductor layer 226 can be thinner than 40 microns, and for a higher voltage rating, the upper semiconductor layer 226 can be thicker than 50 microns. The thicknesses of the layers 224 and 226 may be outside the described ranges if needed or desired for a particular application.

In FIG. 2, dashed lines indicate locations where dopants can be introduced into the upper semiconductor layer 226 by using patterns described in more detail below. In the embodiment as described with respect to FIG. 2, the upper semiconductor layer 226 can includes portions 2262, 2264, 2266, and 2268, where dashed lines illustrate borders between the portions. Although four portions are illustrated, dopants can be introduced at more or fewer locations, and each of the dashed lines can be at a different elevation than as illustrated in FIG. 2. In an embodiment, the portion 2262 of the upper semiconductor layer 226 can be grown from the lower semiconductor layer 224, and a first set of dopants (not illustrated in FIG. 2) can be introduced into the portion 2262 using patterns described in more detail below. The portion 2264 of the upper semiconductor layer 226 can be grown from the portion 2262, and a second set of dopants (not illustrated in FIG. 2) can be introduced into the portion 2264 using patterns described in more detail below. The portion 2266 of the upper semiconductor layer 226 can be grown from the portion 2264, and a third set of dopants (not illustrated in FIG. 2) can be introduced into the portion 2266 using patterns described in more detail below. The portion 2268 of the upper semiconductor layer 226 can be grown from the portion 2266, and a fourth set of dopants (not illustrated in FIG. 2) can be introduced into the portion 2268 using patterns described in more detail below.

In the embodiment, the upper semiconductor layer 226 can be grown without any dopants or is grown in-situ doped with a dopant at a low dopant concentration. For example, the upper semiconductor layer 226 as grown may be undoped or may include an n-type dopant or a p-type dopant where average dopant concentration is at most 1×10¹⁵ atoms/cm³. Dopants can be introduced after growing each portion of the upper semiconductor layer 226 and before growing an overlying portion of the upper semiconductor layer 226. During a subsequent diffusion operation, some dopant from the lower semiconductor layer 224 may diffuse into the portion 2262 of the upper semiconductor layer 226.

Many options are available for doping pillars that are defined by patterning the upper semiconductor layer 226. The different options can be used regarding the amount of charge, average dopant concentrations, and doses for doped regions of the outermost and penultimate pillars within the active region 120. After reading this specification, skilled artisans will appreciate that many other embodiments can be used without deviating from the concepts as described herein. For simplicity, the doped regions within the outermost pillar and penultimate pillars will be compared to p-type doped and n-type doped regions of the interior pillars. Thus, charge and average dopant concentrations are with respect to corresponding charge and average dopant concentration of doped regions within the interior pillars of the active region 120. The term “full” is intended to mean substantially the same charge, average dopant concentration, or dose as compared to a doped region within a corresponding interior pillar.

An electron acceptor-type dopant can accept an electron, and thus, the electron acceptor-type dopant can contribute to negative charge when an electron is accepted. An electron donor-type dopant can donate an electron, and thus, the electron donor-type dopant can contribute to positive charge when an electron is donated.

Table 1 below provides an overview of net charge and average dopant concentration of doped regions within the outermost and penultimate pillars as compared to doped regions within the interior pillars. The different sets of embodiments are described in more detail later in this specification.

TABLE 1
Charge and Dopant Embodiments

| Embodiment | Outermost pillars | Penultimate pillars |
|---|---|---|
| First set | ½ negative charge | full positive charge |
| | ½ average p-type dopant conc. | full average n-type dopant conc. |
| Second set | ½ negative charge | full positive charge |
| | full average p-type dopant conc. | full average n-type dopant conc. |
| | ½ average n-type dopant conc. | |
| Third set | no net charge | ½ positive charge |
| | ½ average p-type dopant conc. | full average n-type dopant conc. |
| | ½ average n-type dopant conc. | ½ average p-type dopant conc. |
| Fourth set | no net charge | ½ positive charge |
| | full average p-type dopant conc. | ½ average n-type dopant conc. |
| | full average n-type dopant conc. | |

The top views in many of the subsequent figures illustrate the dopant and trench patterns relative to one another within the active region 120, and cross-sectional views include portions of the active region 120 and the termination region 130. Each set of embodiments include options with respect to the patterns used during doping. One option can use only stripe-based features, and another option can use a combination of strip-based and block-based features. The option that includes block-based features may allow for more misalignment tolerance as compared to only stripe-based features. In this application, for top views, a direction along an x-axis is in a direction between the left-hand side and the right-hand side of the figure, and a direction along a y-axis is in a direction between the top side and the bottom side of the figure.

### First Set of Embodiments

In a first set of embodiment, the net charge and average dopant concentration of doped regions within the outermost pillars are substantially half of the net charge and average dopant concentration of doped region within the p-type interior pillars. FIG. 3 includes a top view of trenches 300 and pillars 362, 364, 382, and 384 between the trenches 300. Outermost pillars 362 are the pillars closest to the termination region 130 near sides 112 and 114 of the die 110, and the penultimate pillars 382 are the pillars that are next to the outermost pillars 362. Interior pillars 364 are p-type pillars between the penultimate pillars 382, and interior pillars 384 are n-type pillars between the penultimate pillars 382. In an embodiment, the patterns for doping can be achieved using a mask with openings 322 and 324 when doping the die 110 with a p-type dopant, and a mask with openings 342 and 344 when doping the workpiece with an n-type dopant. Thus, the p-type interior pillars 364 within the active regions 120 receive the full dose of p-type dopant, and the n-type interior pillars 384 within the active regions 120 receive the full dose of n-type dopant. The outermost pillars 362 receive approximately half of the full p-type dose because the openings 322 expose approximately half of the outermost pillars 362. The penultimate pillars 382 receive the full n-type dose because the openings 342 expose all of the penultimate pillars 382.

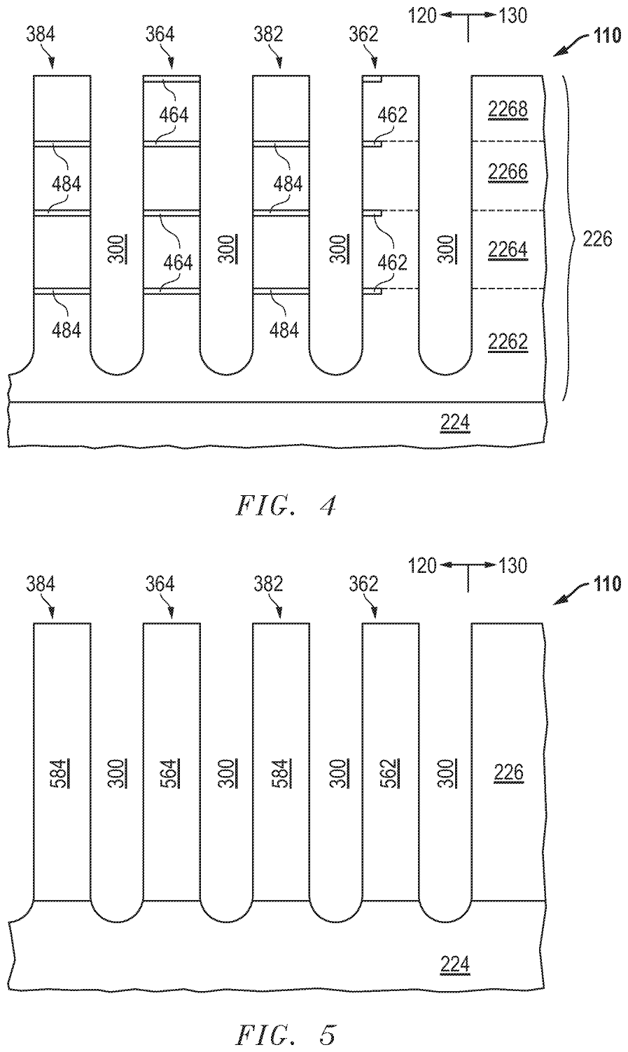

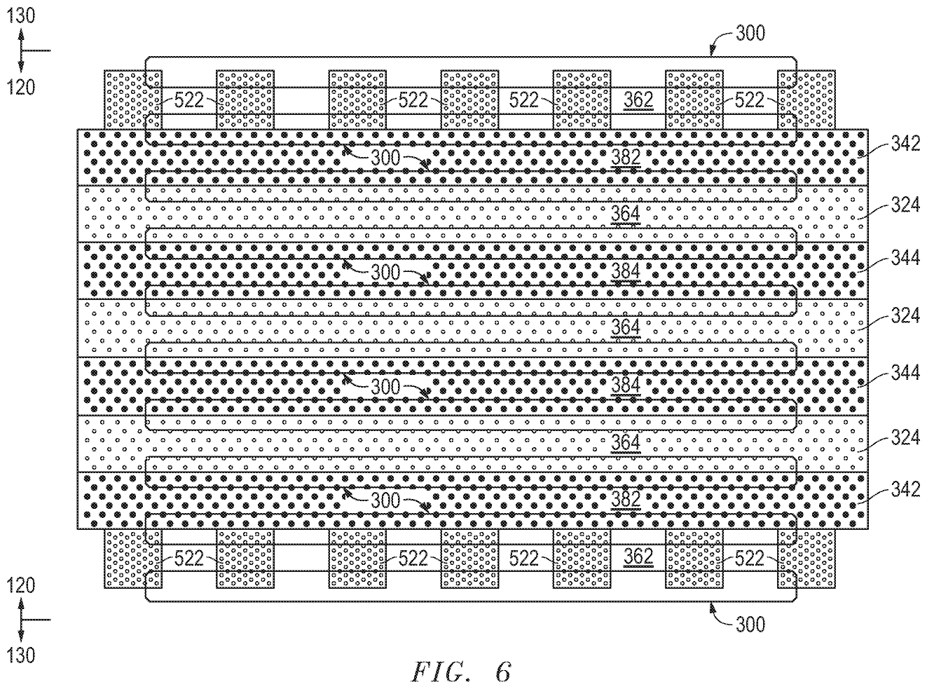

FIG. 4 includes a cross-sectional view of a portion of the workpiece that includes part of the active region 120 and termination region 130 after the substrate is patterned to define the trenches 300 and before a diffusion operation is performed. In an embodiment, the same p-type openings 322 and 324 are used for p-type doping each of the portions 2262, 2264, 2266, and 2268 of the upper semiconductor layer 226, and the same n-type openings 342 and 344 are used for n-type doping each of the potions 2262, 2264, and 2266 of the upper semiconductor layer 226. As illustrated in FIG. 4, the outermost pillar 362 has approximately a half dose of the p-type dopant (depicted as regions 462) as compared to the dose of the interior pillar 364 (depicted as regions 464), and the pillars 382 and 384 have the same dose of n-type dopant (depicted as regions 484). The outermost and penultimate pillars 362 and 382 near the other side of the active region 120 (not illustrated in FIG. 4) are similar as the outermost and penultimate pillars 362 and 382 illustrated in FIG. 4. In an embodiment, the outermost pillar 362 near other side of the active region 120 can be a mirror image of the outermost pillar 362 in FIG. 4, and the penultimate pillars 382 can be substantially the same. The portion 2268 of the upper semiconductor layer 226 for the pillars 382 and 384 are not doped at this point in the process, as source regions, body regions, and gate electrodes will be subsequently formed near the tops of the pillars 382 and 384. In other embodiments, the portion 2268 of the upper semiconductor layer 226 for the pillars 382 and 384 may be doped using the same openings 342 and 344. Furthermore, the dose of the doping may be the same as for portions 2262, 2264, and 2266 or some other value, including doses less than the doses for portions 2262, 2264, and 2266. Such embodiments described with respect to doping the portion 2268 may be applicable to other embodiments described below.

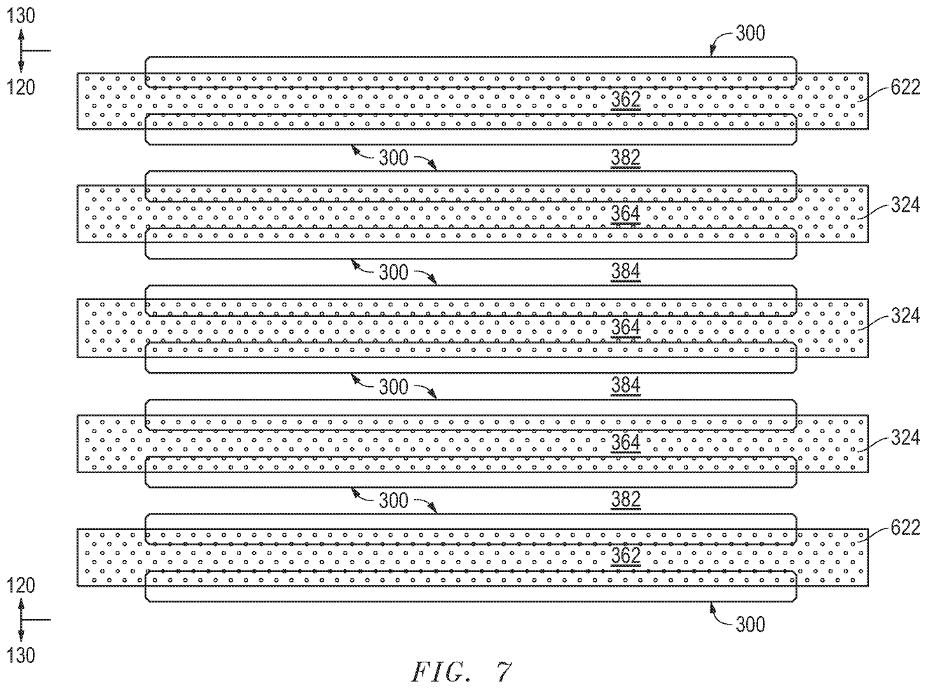

FIG. 5 includes a cross sectional view of the portion of the die 110 after performing a thermal cycle to drive the dopants. Doped region 562 within the outermost pillar 362 has approximately half the net charge and approximately half of the p-type average dopant concentration as compared to doped regions 564 within the p-type interior pillars 364. Doped regions 584 within the penultimate pillars 382 and the n-type interior pillars 384 have substantially the same net charge and substantially the same n-type average dopant concentration.

While the pillars 382 and 384 have n-type dopant that diffuses to the primary surface within the pillars 382 and 384, the dopant concentration near tops of the pillars 382 and 384 may be less than the dopant concentration at a lower elevation closer to the center of the pillars. The lower dopant concentration allows a subsequent p-well doping to form a body region near the tops of the pillars 382 and 384.

Near the bottoms of the pillar 362, 364, 382, and 384, n-type dopant from the lower semiconductor layer 224 or the semiconductor base material 222 can diffuse into lower parts of the pillars 362, 364, 382, and 384. Most of the doping within the pillars 362, 364, 382, and 384 is due to the doping of portions 2262, 2264, 2266, and 2268 of the upper semiconductor layer 226 and thermal dopant drive. Thus, for the pillars 362, 364, 382, and 384, each of the doped regions corresponding to the doping of the portions 2262, 2264, 2266, and 2268 extends along a majority (i.e., more than 50%) of the height of the corresponding pillar.

The layout as illustrated in FIG. 3 may be susceptible to misalignment, particularly in the y-axis direction. For the openings 322, a slight misalignment in the y-axis direction can affect the charge balance along the portions of the active region 120 adjacent to the termination region 130. If the openings 322 are misaligned slightly in the y-axis direction toward the top of FIG. 3, the outermost pillar 362 near the top of FIG. 3 will receive too much dopant, and the outermost pillar 362 near the bottom of FIG. 3 will not receive enough dopant.

FIG. 6 includes sets of openings 522 that replace the openings 322 in FIG. 3. Because the upper and lower edges of the openings 522 terminate in portions of the substrate 200 that will include the trenches 300, the layout in FIG. 6 can tolerate more misalignment in the y-axis direction as compared to the layout in FIG. 3. The spaces between the openings 522 are small enough so that dopant introduced within the openings 522 sufficiently diffuses in the portions of the outermost pillars 362 between the openings 522. In an embodiment, the openings 522 and spaces between the openings 522 may have widths (measured in the x-direction) that are at most 15 microns. In another embodiment, the openings 522 and spaces can have widths in a range from 1.1 microns to 9 microns.

The patterns in FIGS. 3 and 6 can be used to form the doped regions 562 within the outermost pillars 362 that have approximately half of the average dopant concentration of the doped regions 564 within the p-type interior pillars 364. The combination of the doped regions 562 in the two outermost pillars 362 is equivalent to one of the doped regions 564 of the p-type interior pillars 364.

Because the openings 322 and 522 do not overlie all of the outermost pillars 362, the doping concentration within the pillars 362 will not be completely uniform, and thus, the dopant concentration within the pillars 362 may be less uniform as compared to the interior pillars 364 and 384 that receive the full dose. In the first set of embodiments, the active region 120 has the equivalent of four pillars having the full p-type dose and concentration (two outermost pillars 362 each with a half dose and concentration, and three p-type interior pillars 364 each with a full dose and concentration) and four pillars having the full n-type dose and concentration. The doping non-uniformity as described in this paragraph may be applicable to any of the pillars 362 and 382 that receive only part, and not all, of the dose in embodiments as described below.

### Second Set of Embodiments

An insulating layer will be subsequently formed within the trenches 300. The insulating layer can contribute to the charge within the termination region 130. The insulating layer may include an oxide, a nitride, an oxynitride, or a combination thereof. The charge can vary depending on the technique used to form the insulating layer. The insulating layer may be formed using a thermal growth technique or a deposition. The thermal growth may be performed using O₂, O₃, H₂O, N₂O, or NH₃. The deposition can be performed using chemical vapor deposition, with or without plasma assistance, using a variety of different silicon sources and oxygen or nitrogen sources. In an embodiment, the insulating layer can include an oxide and contribute 10% or even more of the total positive charge. Simulations or empirical data can be generated to determine the polarity and amount of charge that is associated with the insulating layer.

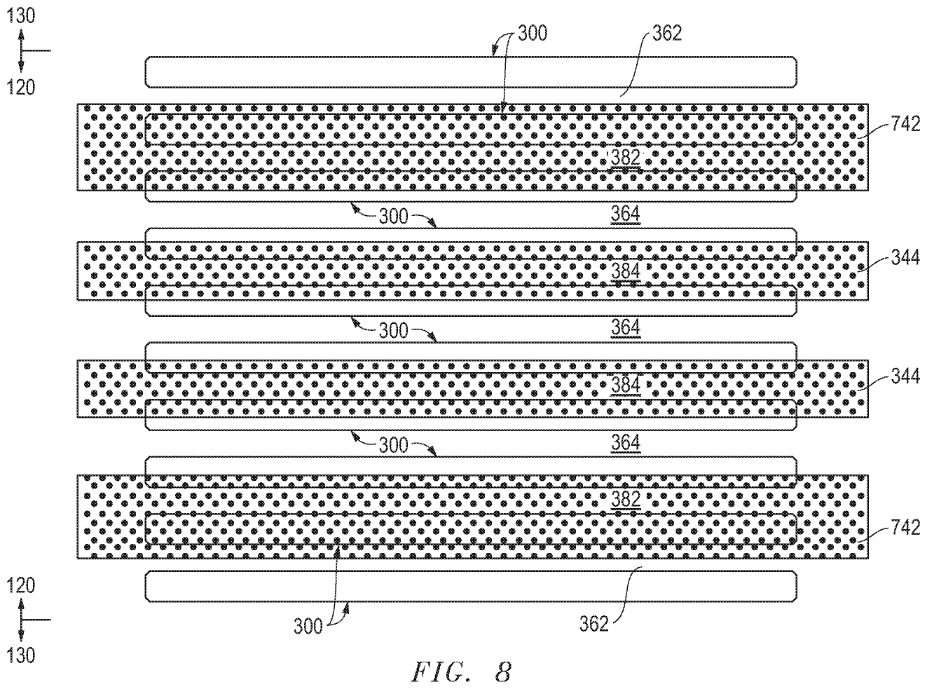

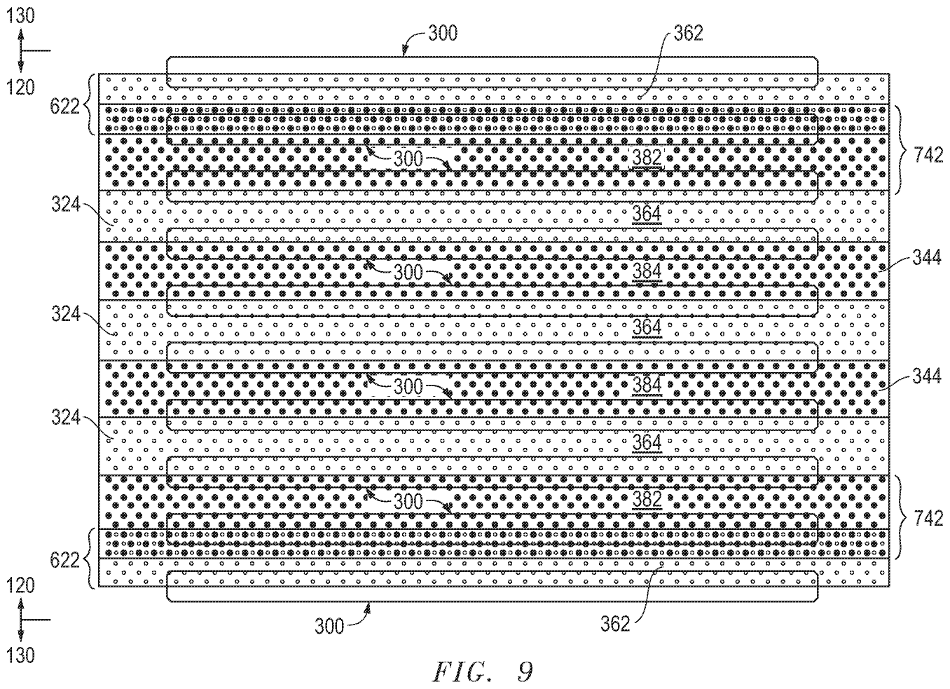

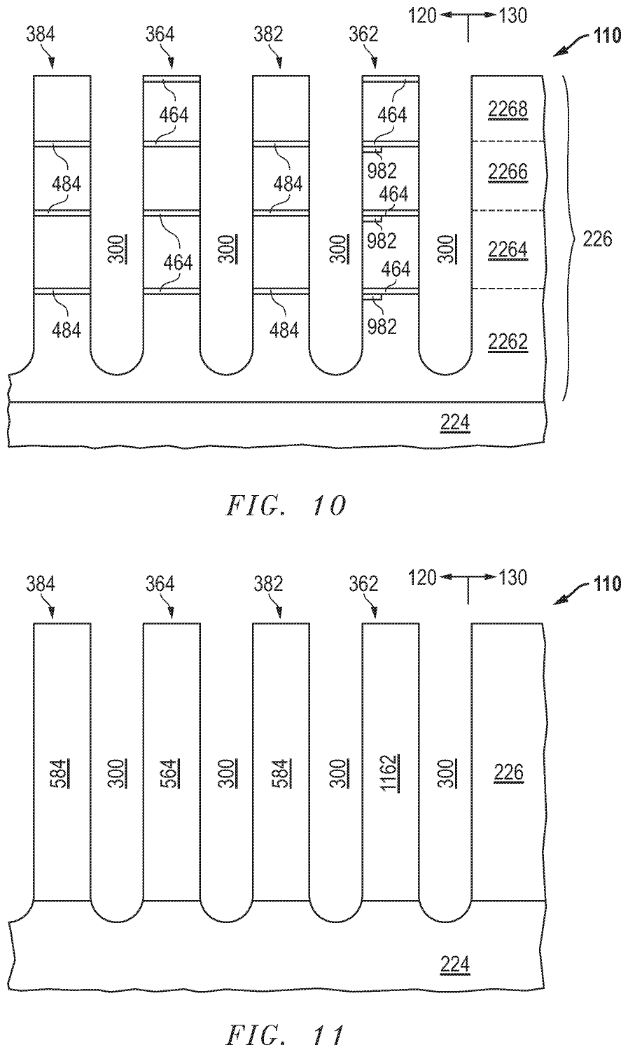

In order to better account for the charge from the insulating layer, as compared to the first set of embodiments, in the second set of embodiments, the active region 120 can have the equivalent of five pillars having the full p-type dose and concentration and five pillars having the full n-type dose and concentration while keeping the number of trenches 300 the same. FIGS. 7, 8, and 9 are top views of the trenches 300 and pillars 362, 364, 382, and 384 between the trenches 300. FIG. 7 includes a top view of a pattern for doping using a mask with openings 622 and 324 that can be used when doping with a p-type dopant, and FIG. 8 includes a top view of a pattern for doping using a mask with openings 742 and 344 that can be used when doping with a n-type dopant. FIG. 9 includes a top view that is a composite of FIGS. 7 and 8 and illustrates the openings 622, 324, 724, and 344 with respect to the pillars 362, 364, 382, and 384.

Referring to FIG. 7, the openings 622 and 324 expose all of the outermost pillars 362 and the p-type interior pillars 364. Thus, the pillars 362 and 364 receive the full p-type dose and after a diffusion operation, the pillars 362 and 364 will have substantially the same p-type average dopant concentration. Referring to FIG. 8, the openings 742 expose half of the outermost pillars 362 and the openings 742 and 344 expose all of the penultimate pillars 382 and the n-type interior pillars 384. Thus, the outermost pillars 362 receive the approximately half of the n-type dose, and the pillars 382 and 384 receive the full n-type dose.

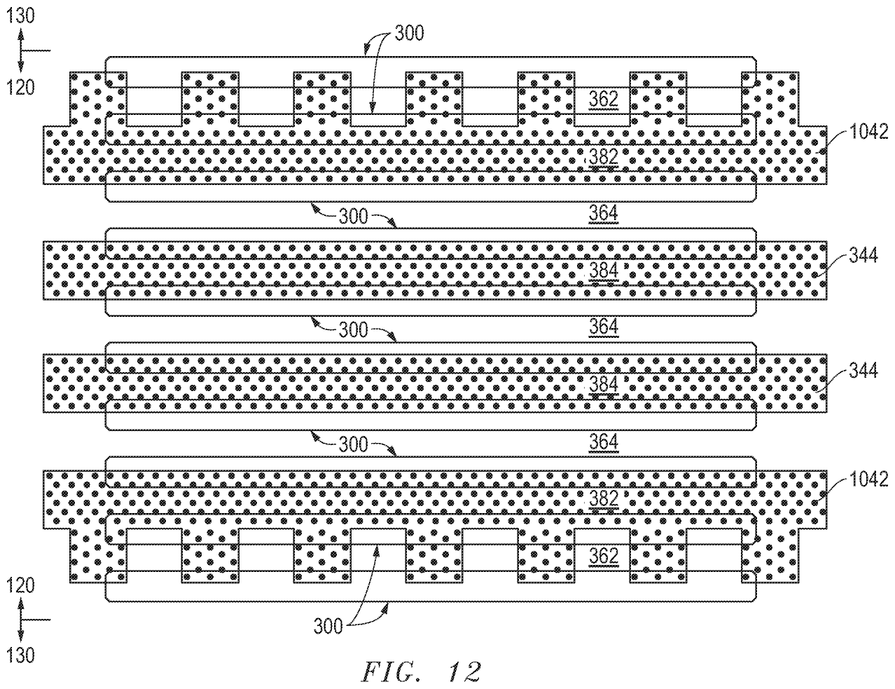

FIG. 10 includes a cross-sectional view of a portion of the die 110 that includes part of the active region 120 and termination region 130 after the substrate is patterned to define the trenches 300 and before a diffusion operation is performed. In an embodiment, the same p-type openings 622 and 324 are used for p-type doping each of the portions 2262, 2264, 2266, and 2268 of the upper semiconductor layer 226, and the same n-type openings 742 and 344 are used for n-type doping each of the potions 2262, 2264, and 2266 of the upper semiconductor layer 226. As illustrated in FIG. 10, the outermost pillar 362 and the p-type interior pillar 364 have the same dose of the p-type dopant (depicted as regions 464) and a half dose of the n-type dopant (depicted as regions 982) as compared to the dose of the pillars 382 and 384 (depicted as regions 484). The outermost and penultimate pillars 362 and 382 near the other side of the active region 120 (not illustrated in FIG. 10) are similar as the outermost and penultimate pillars 362 and 382 illustrated in FIG. 10. In an embodiment, the outermost pillar 362 near other side of the active region 120 can be a mirror image of the outermost pillar 362 in FIG. 10, and the penultimate pillars 382 can be substantially the same. The portion 2268 of the upper semiconductor layer 226 for the pillars 382 and 384 are not doped at this point in the process, as source regions, body regions, and gate electrodes will be subsequently formed near the tops of the pillars 382 and 384.

Although regions 464 and 982 are illustrated at different elevations within each of the portions 2262, 2264, and 2266, the regions 464 and 982 may overlap or be at the same elevation. The widths of the regions 464 and 982 (as measured in the vertical direction) are substantially smaller than the distance dopants diffuse within the outermost pillar 362 during a subsequent diffusion operation. The portion 2268 of the upper semiconductor layer 226 for the pillars 362, 382 and 384 are not doped with an n-type dopant at this point in the process.

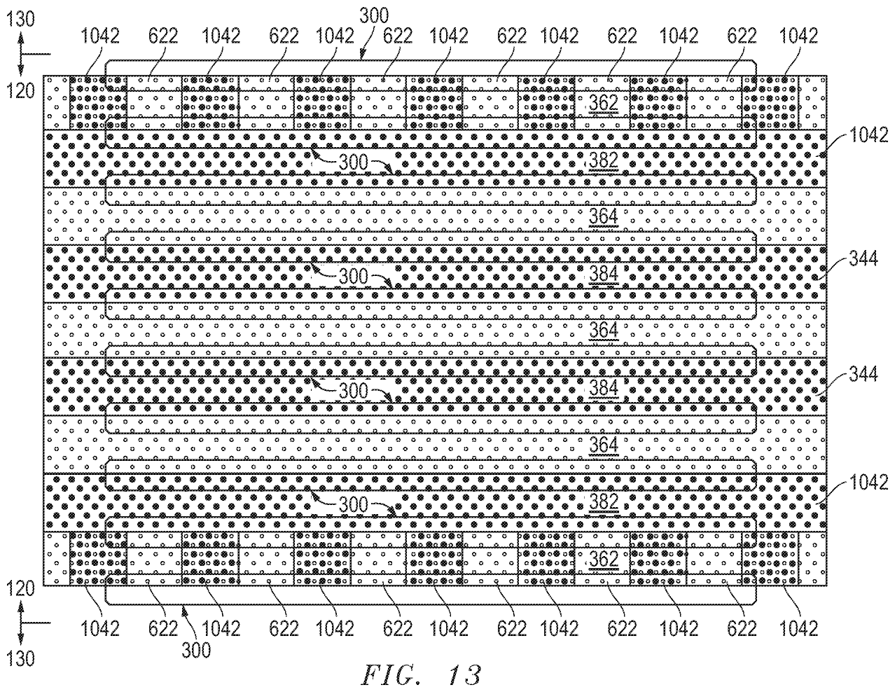

FIG. 11 includes a cross sectional view of the portion of the die 110 after performing a thermal cycle to drive the dopants. Doped region 1162 within the outermost pillar 362 has approximately half the net charge of the doped regions 564 within the p-type interior pillars 364. With respect to dopants, the doped region 1162 has substantially the same p-type average dopant concentration as the doped regions 564 within the p-type interior pillars 364, and the outermost pillar 362 is partly counter doped by approximately half of the n-type average dopant concentration as compared to the doped regions 584 within the penultimate pillars 382 and the n-type interior pillars 384.

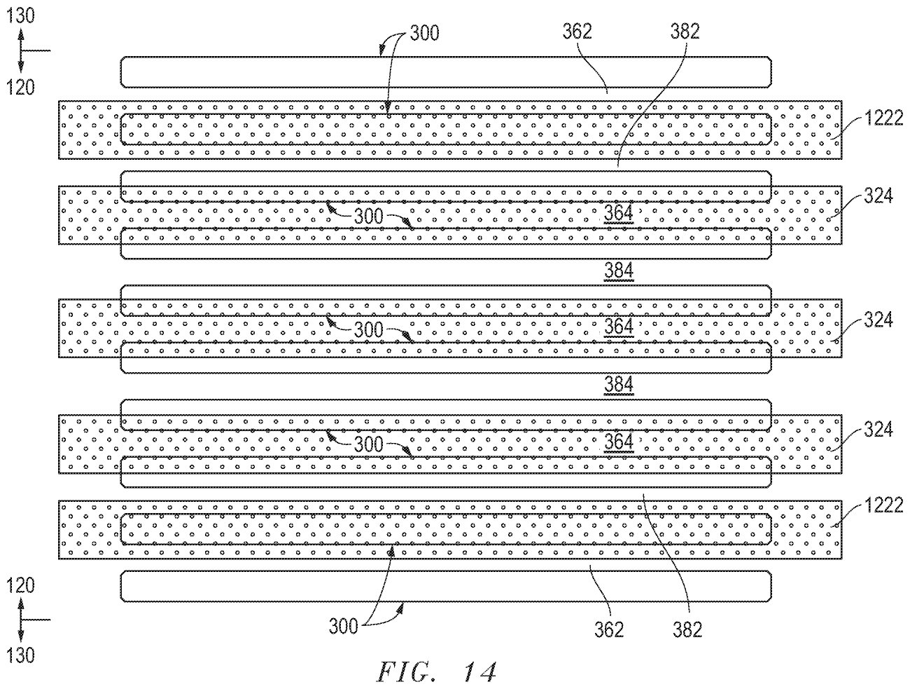

Similar to FIG. 6 in the first set of embodiments, a block-style implant mask may help improve tolerance to misalignment. The openings 622 and 324 in FIG. 7 are used for the p-type doping. The pattern in FIG. 8 is replaced with the pattern as illustrated in FIG. 12. The openings 1042 in FIG. 12 replace the openings 742 in FIG. 8. Because the upper and lower edges of the openings 1042 terminate in portions of the substrate 200 that will include the trenches 300, the layout in FIG. 12 can tolerate more misalignment in the y-axis direction as compared to the layout in FIG. 8. Similar to FIG. 6, the spaces between the openings 1042 in FIG. 12 are small enough to allow dopant introduced within the openings 1042 to sufficiently diffuse between the openings 1042. In an embodiment, the openings 1042 and spaces between the openings 1042 can have any of the dimensions as previously described with respect to the openings 522 and spaces between the openings 522. FIG. 13 includes a composite of the patterns in FIGS. 7 and 12 and illustrates the openings 324, 344, 622, and 1042 and the trenches 300 relative to one another. The pillars 362 receive the full dose of a p-type dopant because of the openings 622 and half of the dose of the n-type dopant because of the openings 1042.

### Third Set of Embodiments

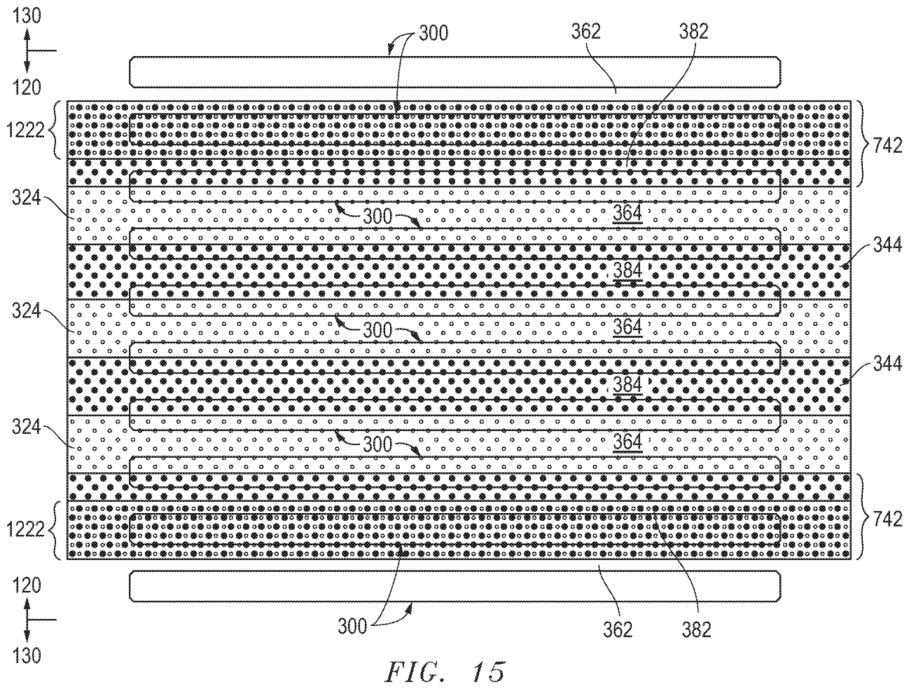

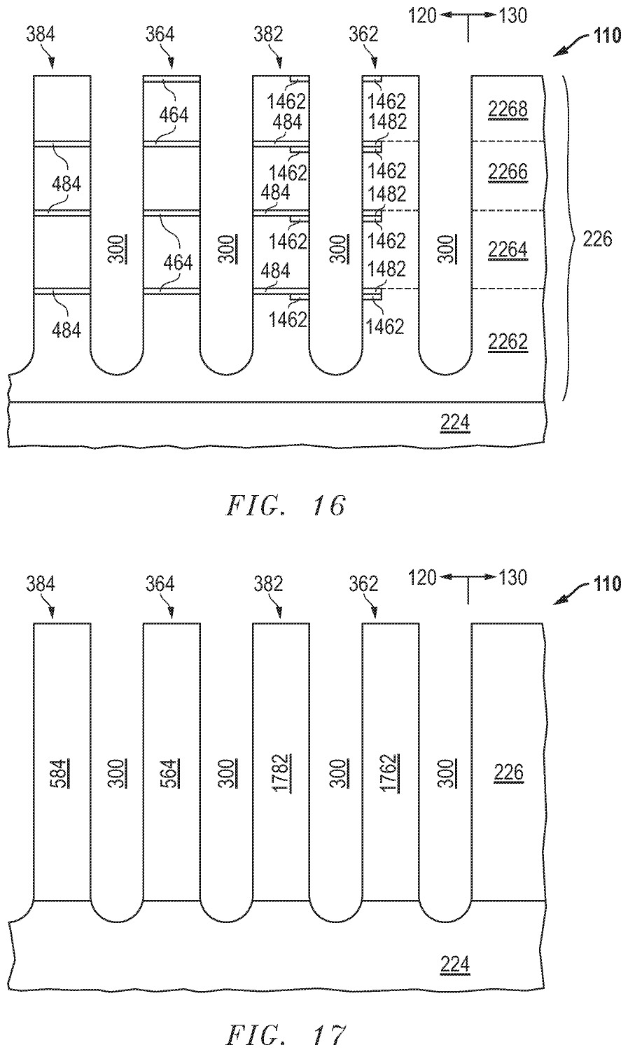

The breakdown voltage can be increased when (1) the outermost pillars 362 have substantially no net charge by using a half p-type dose and a half n-type dose and (2) the penultimate pillars 382 have substantially half of the net charge of the interior pillars 384 by using a full n-type dose and a half p-type dose. FIG. 14 includes a top view of a lithographic pattern with openings 1222 and 324 that can be used when doping with a p-type dopant. FIG. 8 includes a view of a lithographic pattern used for the n-type dopant. FIG. 15 includes a top view that is a composite of FIGS. 8 and 14 and illustrates the openings 1222, 324, 742, and 344 with respect to the pillars 362, 364, 382, and 384.

Referring to FIG. 14, the openings 1222 exposed half of the outermost pillars 362 and half of the penultimate pillars 382. The openings 324 expose all of the p-type interior pillars 364. Thus, the pillars 362 and 382 receive approximately half of the p-type dose, and the p-type interior pillars 364 receive the full p-type dose. After a diffusion operation, the pillars 362 and 382 will have substantially the same p-type average dopant concentration that is approximately half of the p-type average dopant concentration of the p-type interior pillars 364. The pattern illustrated in FIG. 8 is used for the n-type doping and is described in more detail above. After a diffusion operation, the pillars 382 and 384 will have substantially the same n-type average dopant concentration, and the outermost pillars 362 will have approximately half of the n-type average dopant concentration of the pillars 382 and 384.

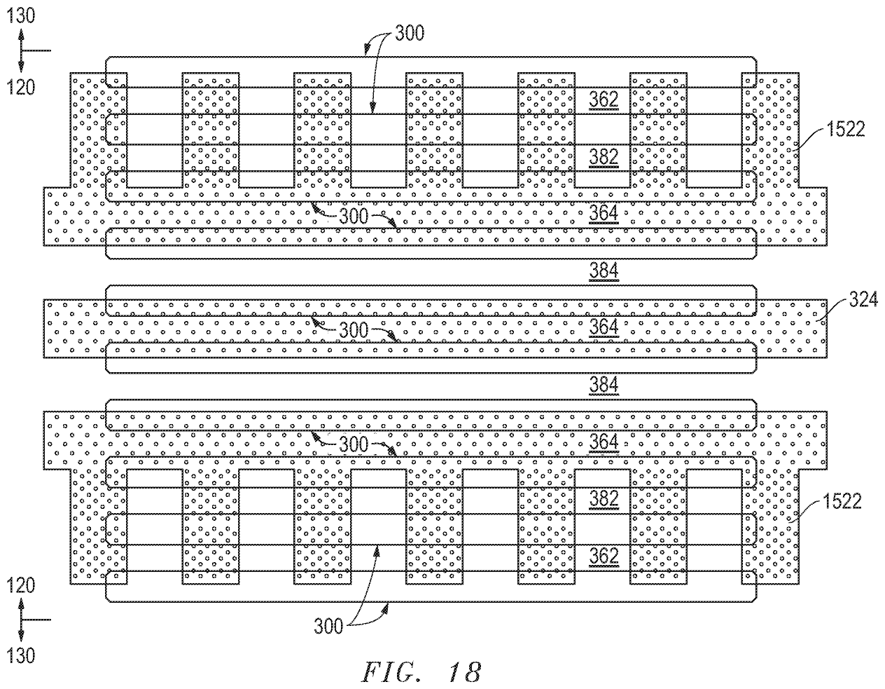

FIG. 16 includes a cross-sectional view of a portion of the workpiece that includes part of the active region 120 and termination region 130 after the substrate is patterned to form the trenches 300 and before a diffusion operation is performed. In an embodiment, the same p-type openings 1222 and 324 are used for p-type doping each of the portions 2262, 2264, 2266, and 2268 of the upper semiconductor layer 226, and the same n-type openings 742 and 344 are used for n-type doping each of the potions 2262, 2264, and 2266 of the upper semiconductor layer 226. As illustrated in FIG. 16, the outermost pillar 362 and the penultimate pillar 382 have approximately half of the dose of the p-type dopant (depicted as regions 1462) as compared to the dose for the p-type interior pillars 364 (depicted as regions 464). The outermost pillar 362 has approximately half dose of the n-type dopant (depicted as regions 1482) as compared to the dose for the pillars 382 and 384 (depicted as regions 484). In the embodiment, as illustrated in FIG. 16, the portion 2268 of the upper semiconductor layer 226 for the pillars 362, 382 and 384 is not doped with an n-type dopant at this point in the process, as source regions, body regions, and gate electrodes will be subsequently formed near the tops of the pillars 382 and 384.

Regarding the pillars 362 and 382, although regions 484, 1462, and 1482 are illustrated at different elevations within each of the portions 2262, 2264, and 2266, the regions 484, 1462, and 1482 may overlap or be at the same elevation. The widths of the regions 484, 1462, and 1482 (as measured in the vertical direction) are substantially smaller than the distance dopants diffuse within the pillars 362 and 382 during a subsequent diffusion operation. In an embodiment, the pillars 362 and 382 near the other side of the active region 120 can be mirror images of the pillars 362 and 382 in FIG. 16.

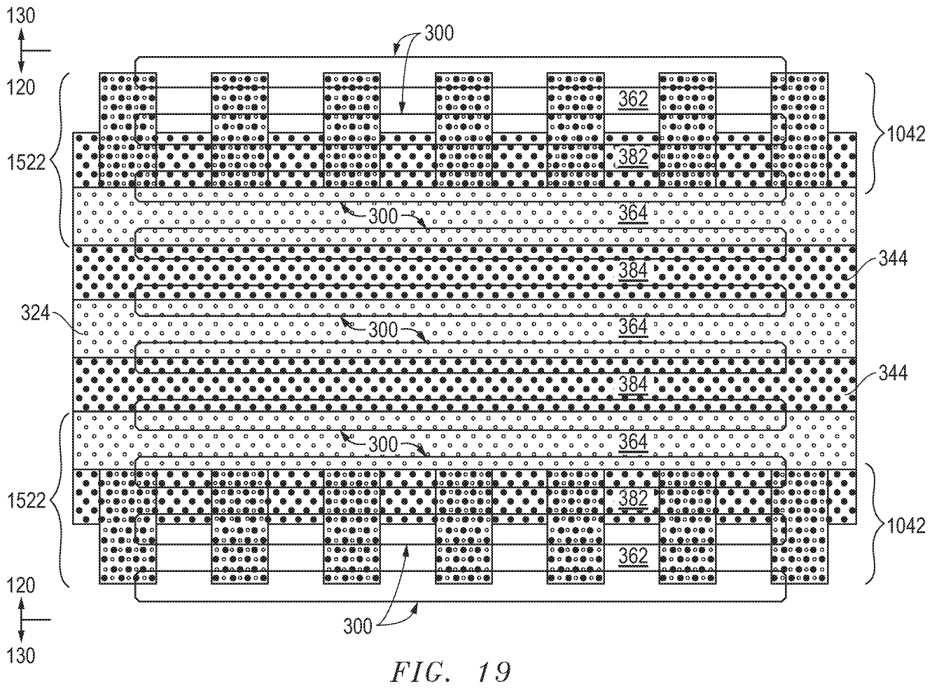

FIG. 17 includes a cross sectional view of the portion of the die 110 after performing a thermal cycle to drive the dopants. Doped region 1762 within the outermost pillar 362 has substantially zero net charge, and doped region 1782 within the penultimate pillar 382 has approximately half the net charge of the doped region 584 within the n-type interior pillar 384. With respect to dopants, the doped regions 1762 and 1782 have approximately half of the p-type average dopant concentration as compared to the doped region 564 of the p-type interior pillar 364. The doped region 1762 of the outermost pillar 362 has approximately half of the n-type average dopant concentration as compared to the doped region 1782 of the penultimate pillar 382 and the doped region 584 of the n-type interior pillar 384. The doped region 1782 has substantially the same n-type average dopant concentration as the doped region 584 within the n-type interior pillar 384.

Similar to FIG. 6 in the first set of embodiments, a block-style implant mask may help improve tolerance to misalignment. The openings 1522 and 324 in FIG. 18 are used for p-type doping. The lithographic pattern in FIG. 12 is used for n-type doping. Referring to FIG. 18, because the upper and lower edges of the openings 1522 terminate in portions of the substrate 200 that will include the trenches 300, the layout in FIG. 18 can tolerate more misalignment in the y-axis direction as compared to the layout in FIG. 14. Similar to FIG. 6, the spaces between the openings 1522 in FIG. 18 are small enough to allow dopant introduced within the openings 1522 to sufficiently diffuse between the openings 1522. In an embodiment, the openings 1522 and spaces between the openings 1522 can have any of the dimensions as previously described with respect to the openings 522 and spaces between the openings 522. FIG. 19 includes a composite of the patterns in FIGS. 12 and 18 to illustrate the relative positions of the openings 1042, 344, 1522, and 324 and the trenches 300 relative to one another. The pillars 362 and 382 receive approximately half dose of a p-type dopant because of the openings 1522. The outermost pillar 362 receives approximately half of the dose of the n-type dopant, and the penultimate pillar 382 receives the full n-type dose because of the openings 1042.

### Fourth Set of Embodiments

In the third set of embodiments, the penultimate pillars 382 may be inactive because the portion 2268 of the upper semiconductor layer 226 for the penultimate pillars 382 are doped with the p-type dopant. In a finished device, the p-type doped region within the portion 2268 will diffuse within the pillars 382 (along with pillars 362 and 364). With respect to the penultimate pillars 382, the p-type dopant within the upper portion 2268 of the upper semiconductor layer 226 will not allow the positively charged portions 2262, 2264, and 2266 to be electrically connected to the source terminal when the transistor structures including the penultimate pillars 382 are turned on. In this fourth set of embodiment, p-type dopant is not used within the penultimate pillars 382 at this point in the process. The penultimate pillars 382 may subsequently receive a p-well implant that is part of a body region for the transistor structures within the penultimate pillars 382.

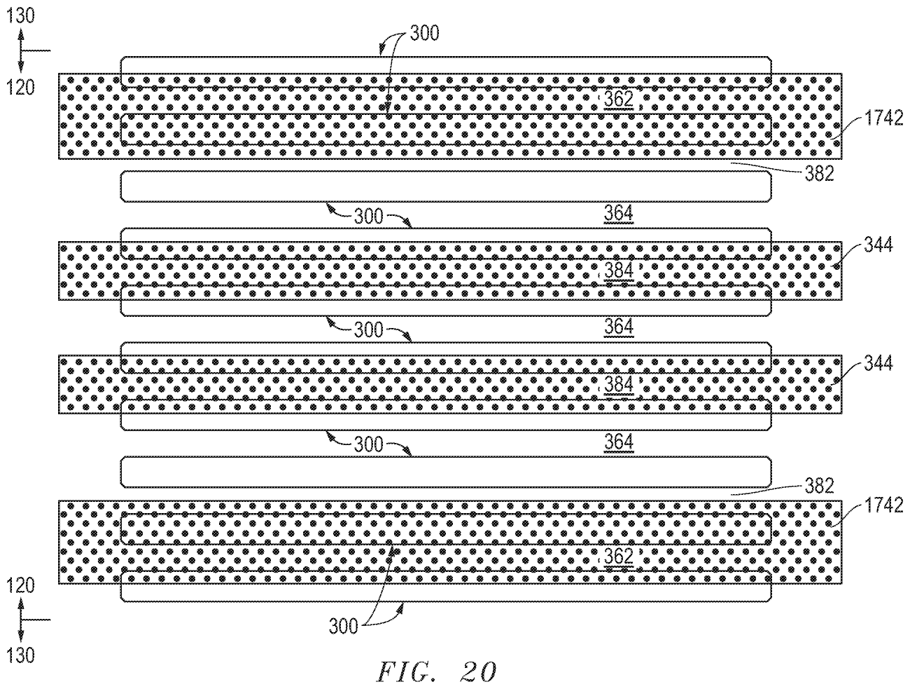

P-type doping is performed using the pattern as previously described with respect to FIG. 7. FIG. 20 includes a pattern that can be used for n-type doping. FIG. 21 includes a top view that is a composite of FIGS. 7 and 20 and illustrates the openings 622, 324, 1742, and 344 with respect to the pillars 362, 364, 382, and 384.

Referring to FIG. 20, the openings 1742 expose all of the outermost pillars 362 and half of the penultimate pillars 382. The openings 344 expose all of the interior pillars 384. Thus, the pillars 362 and 384 receive the full n-type dose, and after a diffusion operation, the penultimate pillars 382 will have approximately half of the n-type average dopant concentration as compared to the pillars 362 and 384.

After a diffusion operation, the pillars 362 and 364 will have substantially the same p-type average dopant concentration, and the pillars 362 and 384 will have substantially the same n-type average dopant concentration. The penultimate pillars 382 will have approximately half of the n-type average dopant concentration of the pillars 362 and 384. Accordingly, the outermost pillars 362 have substantially no net charge, the p-type interior pillars 364 have substantially the full net negative charge, the n-type interior pillars 384 have substantially the full net positive charge, and the penultimate pillars 382 have approximately half of the net positive charge of the n-type interior pillars 384.

FIG. 22 includes a cross-sectional view of a portion of the workpiece that includes part of the active region 120 and termination region 130 after the substrate is patterned to form the trenches 300 and before a diffusion operation is performed. In an embodiment, the same p-type openings 622 and 324 are used for p-type doping each of the portions 2262, 2264, 2266, and 2268 of the upper semiconductor layer 226, and the same n-type openings 1742 and 344 are used for n-type doping each of the potions 2262, 2264, and 2266 of the upper semiconductor layer 226. As illustrated in FIG. 22, the outermost pillar 362 and the interior pillar 364 have a full dose of the p-type dopant (depicted as regions 464), and the outermost pillar 362 and the interior pillar 384 have the full dose of the n-type dopant (depicted as regions 484). The penultimate pillar 382 has approximately half of the dose of the n-type dopant (depicted as regions 1942), as compared to the pillars 362 and 384. The portion 2268 of the upper semiconductor layer 226 for the pillars 382 and 384 are not doped at this point in the process, as source regions, body regions, and gate electrodes will be subsequently formed near the tops of the pillars 382 and 384.

Although regions 464 and 484 are illustrated at different elevations within each of the portions 2262, 2264, and 2266 for the outermost pillar 362, the regions 464 and 484 within the outermost pillar 362 may overlap or be at the same elevation. The widths of the regions 464 and 484 (as measured in the vertical direction) within the outermost pillar 362 are substantially smaller than the distance dopants diffuse within the outermost pillar 362 during a subsequent diffusion operation. The penultimate pillars 362 within the active region 120 can be substantially the same. In an embodiment, the penultimate pillar 382 near other side of the active region 120 can be a mirror image of the penultimate pillar 382 in FIG. 22. The portion 2268 of the upper semiconductor layer 226 for the pillars 362, 364, 382 and 384 are not doped with an n-type dopant at this point in the process.

FIG. 23 includes a cross sectional view of the portion of the die 110 after performing a thermal cycle to drive the dopants. Doped region 2362 has substantially zero net charge because the outermost pillar 362 receives the full p-type dose and the full n-type dose. Doped region 2382 within the penultimate pillar 382 has approximately half the net charge of the doped regions 584 within the n-type interior pillars 384. With respect to dopants, the doped region 2362 has substantially the same p-type average dopant concentration as compared to the doped region 564 within the p-type interior pillar 364 and substantially the same n-type average dopant concentration as compared to the doped region 584 within the n-type interior pillar 384. The doped regions 2382 within penultimate pillar 382 has approximately half of the n-type average dopant concentration as compared to the doped region 584 within the n-type interior pillar 384.

Similar to FIG. 6 in the first set of embodiments, a block-style implant mask may help improve tolerance to misalignment. The pattern in FIG. 7 is used for p-type doping, and the pattern in FIG. 24 is used for n-type doping. Referring to FIG. 24, because the upper and lower edges of the openings 2042 terminate in portions of the substrate 200 that will include the trenches 300, the layout in FIG. 24 can tolerate more misalignment in the y-axis direction as compared to the layout in FIG. 20. Similar to FIG. 6, the spaces between the openings 2042 in FIG. 24 are small enough to allow dopant introduced within the openings 2042 to sufficiently diffuse between the openings 2042. In an embodiment, the openings 2042 and spaces between the openings 2042 can have any of the dimensions as previously described with respect to the openings 2042 and spaces between the openings 522.

FIG. 25 includes a composite of the patterns in FIGS. 7 and 24 to illustrate the relative positions of the openings 622, 324, 2042 and 344 and the trenches 300 relative to one another. The pillars 362 and 364 receive the full dose of a p-type dopant because of the openings 622 and 324, the pillars 362 and 384 receive the full dose of the n-type dopant because of the openings 2042 and 344. The penultimate pillars 382 receive approximately half of the dose of the n-type dopant because of the block portions of and spaces between openings 2042 that extend over the penultimate pillars 382.

Unlike the third set of embodiments, the fourth set of embodiments allows for a substantially zero net charge within a pillar that is not designed to have electrons flowing through such pillar when the transistor is in an on-state. In each of the previously described embodiments, the outermost pillars 362 and the p-type interior pillars 364 do not have electrons flowing through such pillars when the transistor is in the on-state. In the fourth set of embodiments, the penultimate pillars 382 have less net charge that is achieved without partial counter doping as described with respect to the third set of embodiments. Accordingly, current can flow through the penultimate pillars 382 when the transistor is in the on-state. The on-state resistance for the penultimate pillars 382 in the fourth set of embodiments will be higher than the on-state resistance for the penultimate pillars 382 in the first and second sets of embodiments; however, the higher resistance is better than inactive pillars that occur with the penultimate pillars 382 in the third set of embodiments.

Other designs are possible. Many of the prior embodiments describe pairs of outermost and penultimate pillars that have doping different from the interior pillars 364 and 384. Doses and average dopant concentrations are described in terms of full doses and full concentrations and half doses and half concentrations. As previously described, in practice, the active region 120 can include hundreds or thousands of trenches and pillars. If needed or desired, one or more additional pillars can be doped to achieve a more gradual transition of the net charge between the center of the active region 120 and parts of the active region 120 that are closer to the termination region 130. In an embodiment, another pair of pillars that are adjacent to the penultimate pillars 382 may also have partially doped or partially counter doped regions. For example, the outermost pillars 362 may have substantially zero net charge, the penultimate pillars 382 may have approximately a quarter of the net charge of an n-type interior pillar 384 near the center of the active region 120, the pillars 364 closest to the penultimate pillars 382 may have approximately half of the net charge of a p-type interior pillar 364 near the center of the active region 120, and the pillars 384 closest to the penultimate pillars 382 may have approximately three quarters of the net charge of an n-type interior pillar 384 near the center of the active region 120. After reading this specification, skilled artisans will be able to determine a design to allow for a gradual transition of net charge within the active region 120 near the boundaries with the termination region 130.

Processing continues to complete formation of the transistor structures within the active region 120. The remainder of the process is described starting with the embodiment illustrated in FIG. 23 (fourth set of embodiments). The processing described below may be used for any of the previously described embodiments. Subsequently processing described below includes a non-limiting embodiment, and other embodiments can be used for different designs without deviating from the concepts as described herein.

FIG. 26 includes a portion of the die 110 after forming a semiconductor layer, recessing the semiconductor layer within the trenches, and forming an insulating layer. From a top view, the transistor structures will have gate electrodes within the centers of the pillars 382 and 384 and source regions on opposite sides of the gate electrodes. The semiconductor layer allows for contact to be subsequently formed to the source regions and body contact regions. The semiconductor layer can also reduce the widths of the trenches 300, so that less insulating material may be used when sealing off the trenches 300.

In an embodiment, a semiconductor layer is formed using a selective epitaxial growth to increase the width of the pillars 362, 364, 382, and 384. Although not illustrated, a protective layer, such as an oxide layer or a nitride layer, can overlie the pillars 362, 364, 382, and 384 before the semiconductor layer is formed and be used to protect the pillars 362, 364, 382, and 384 when defining the trenches 300. The semiconductor layer can be epitaxially grown from exposed portions of the substrate 200. The semiconductor layer can have a thickness in a range from 0.1 micron to 0.9 micron.

An anisotropic etch may be performed to recess the semiconductor layer within the trenches 300. In FIG. 26, the border between the original pillars (when defining the trenches) and the semiconductor layer is illustrated with dashed lines. Each of the pillars includes its original pillar at the center of the pillar and the semiconductor layer along opposite sides of the original pillar. The dashed lines are not illustrated in subsequent figures, and the pillars in subsequent figures include the original pillars and remaining portions of the semiconductor layer.

The protection layer over the pillars may or may not be removed at this point in the process. For the embodiment as illustrated in FIG. 26, the protective layer is removed. The insulating layer 2602 is formed along exposed surfaces of the pillars 362, 364, 382, and 384. The insulating layer 2602 can include one or more films of an oxide or a nitride. As previously described, the insulating layer 2602 may affect the charge within the active region 120. Thus, the insulating layer 2602 may be formed in a manner consistent with a prior simulation or prior empirical testing, so that the net charge associated with the insulating layer 2602 is sufficiently close to the net charge corresponding to the simulation or testing. In a particular embodiment, the insulating layer 2602 is thermally grown using H₂O. In another embodiment, the insulating layer 2602 can be formed by thermally growing in O₂ or the other oxidizing species previously described. In further embodiments, the insulating layer 2602 may be formed by chemical vapor deposition, with or without plasma assistance. A subsequent thermal operation, such as a high temperature anneal to reduce stress or to densify a deposited layer, may affect net charge, so such thermal operation should have been considered during the simulation or testing. The thickness of the insulating layer 2602 is in a range from 50 nm to 300 nm.

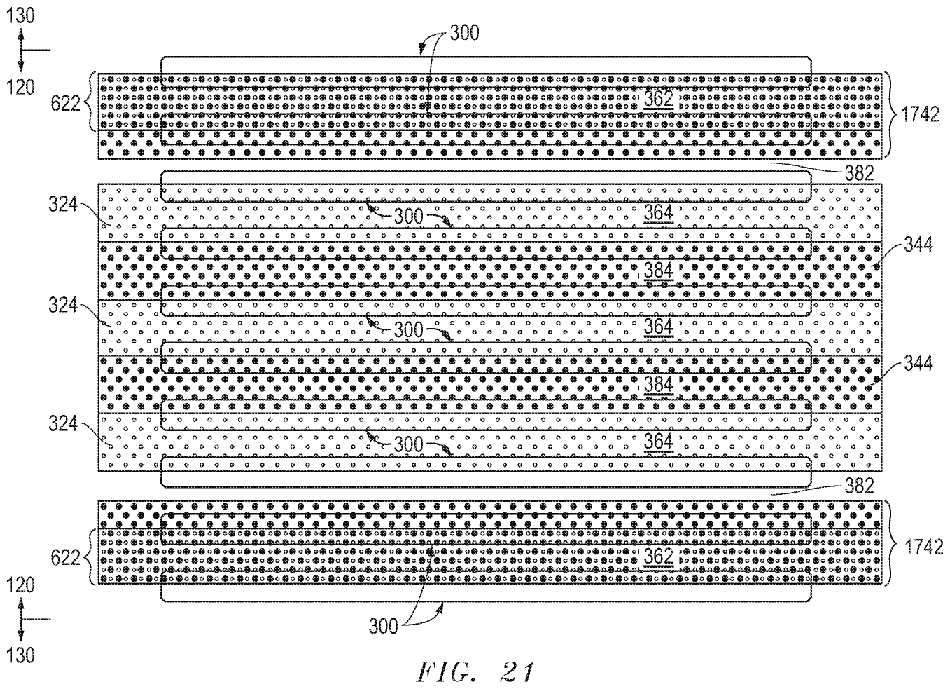

FIG. 27 includes the portion of the die 110 after forming p-well regions 2702, a gate dielectric layer 2714, gate electrodes 2724, and source regions 2728. As compared to FIG. 26, FIG. 27 illustrates upper portions of the pillars 362, 364, 382, and 384 and a portion of the termination region 130. Although not illustrated, portions of the trenches 300 may be at least partly filled with a sacrificial layer that can help to keep dopant from being introduced into the substrate 200 under the trenches 300 and into sidewalls along lower portions of the pillars 362, 364, 382, and 384. The p-well regions 2702 are formed within the substrate 200 near the primary surface and include the active region 120, the termination region 130, and the peripheral region 140. The depths of the p-well regions 2702 can affect the channel lengths of the transistor structures being formed within the pillars 382 and 384. The lowermost elevations of the p-well regions 2702 are at higher elevations than the lowermost elevations of the gate electrodes 2724. The elevational differences between (1) the lowermost elevations of source regions 2728 at gate openings and (2) the lowermost elevations of the p-well regions 2702 correspond to the channel lengths of the transistor structures. In an embodiment, the depth of the p-wells 2702, as measured from the primary surface 225, is in a range from approximately 0.5 micron to 3.0 microns. The average dopant concentration of the p-well regions 2702 affects the threshold voltage of the transistor structures. In an embodiment, the average dopant concentration of the p-well regions 2702 is in a range from 5×10¹⁵ atoms/cm³ to 5×10¹⁷ atoms/cm³.

The penultimate pillars 382 and the n-type interior pillar 384 are patterned to define openings where the gate electrodes 2724 are formed. The openings extend to a depth lower than the lowermost elevations of the p-well regions 2702. In an embodiment, the depth of the gate openings can extend 0.05 micron to 0.5 micron farther into the pillars 382 and 384 as compared to bottoms of the p-well regions 2702.

The gate dielectric layer 2714 is formed along exposed surfaces of the pillars 382 and 384 within the gate openings. The gate dielectric layer 2714 can include an oxide, a nitride, or an oxynitride. In an embodiment, the gate dielectric layer 2714 has a thickness in a range from 11 nm to 200 nm. The gate dielectric layer 2714 can be formed using a thermal growth, a deposition, or a combination thereof.

The gate electrodes 2724 can be formed by depositing a conductive layer over the die 110 and the gate dielectric layer 2714 and within the openings for the gate electrodes 2724. The conductive layer can include one or more conductive films. In an embodiment, the conductive layer includes a heavily doped semiconductor layer so that ohmic contacts can subsequently be formed to the heavily doped semiconductor layer. In another embodiment, the conductive layer can include a metal film, such as a tungsten layer, and may or may not include an adhesion film, a barrier film, or the like. Portions of the conductive layer outside the gate openings are removed to complete formation of the gate electrodes 2724.

Source regions 2728 are formed in the penultimate pillar 382 and n-type interior pillar 384. The source regions 2728 are shallow as compared to many of the other doped regions previously described in this specification. The source regions can be n-type heavily doped regions that allow ohmic contacts to subsequently-formed interconnects. In an embodiment, the depth of the source regions 2728 are in a range from 0.05 micron to 0.8 micron as measured from the primary surface 225.

In an alternative embodiment, the gate electrodes 2724 can be formed by depositing an undoped or lightly doped semiconductor layer and doping the semiconductor layer at the same time the source regions 2728 are formed. After reading this specification, skilled artisans will be able to determine a process integration with respect to the formation of the gate electrodes 2724 and source regions 2728 to meet the needs or desires for a particular application.

If an optional sacrificial layer was formed within the trenches 300, the sacrificial layer can be removed at this point in the process.

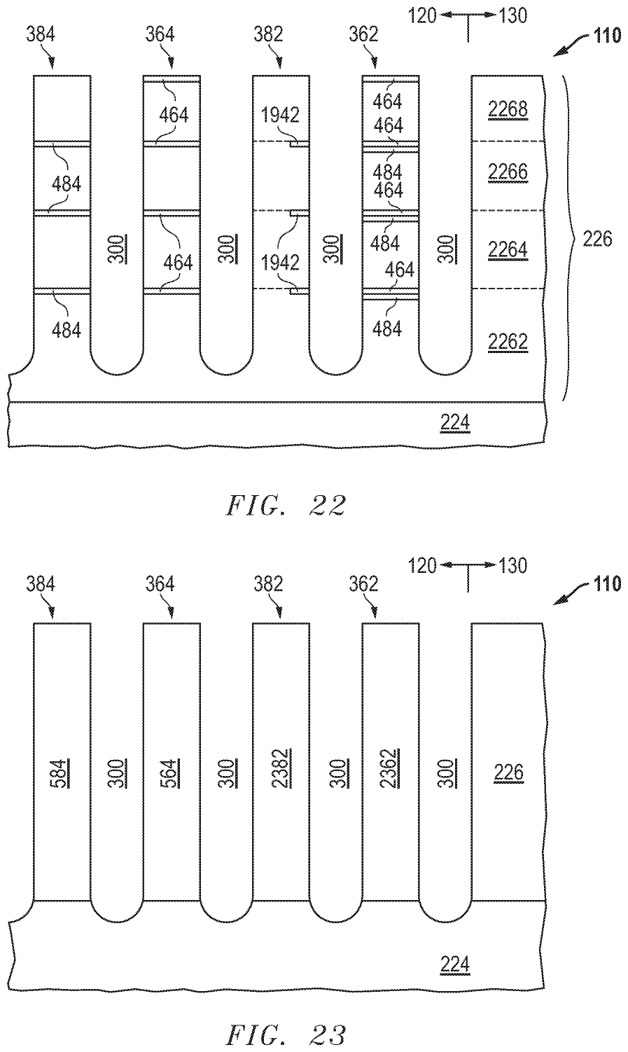

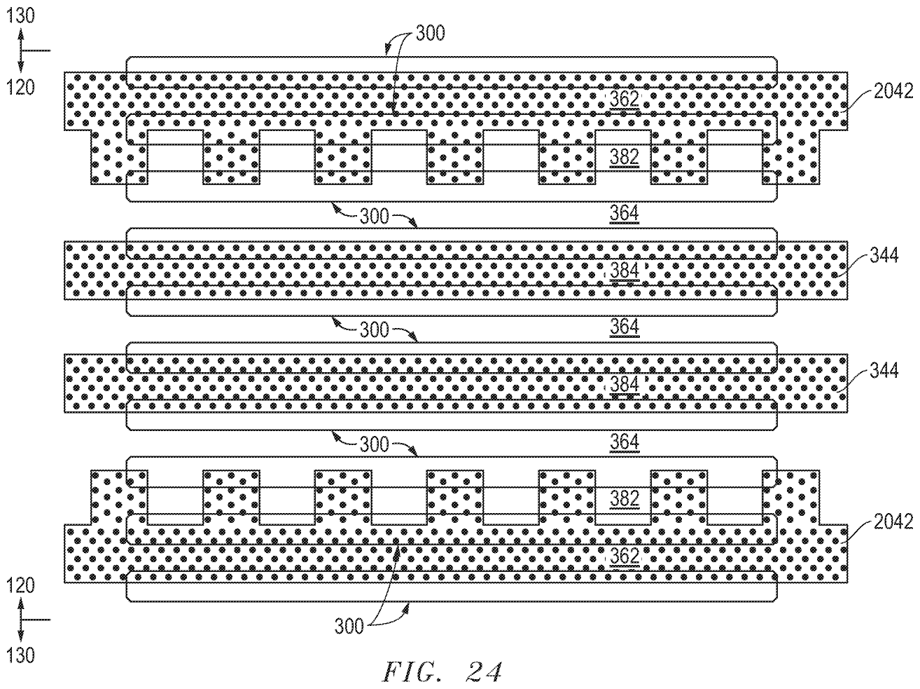

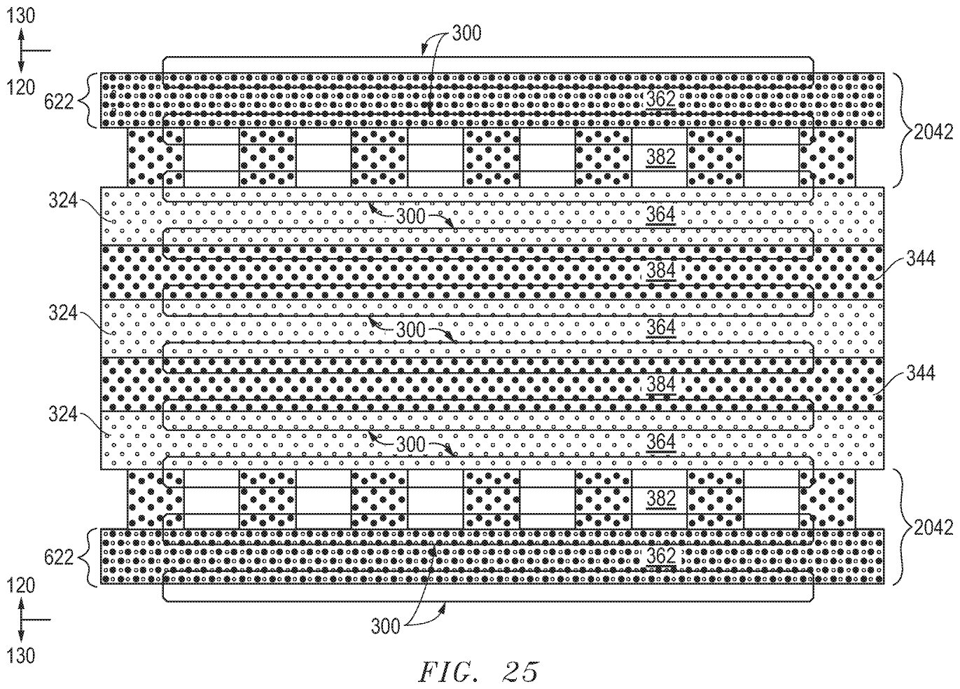

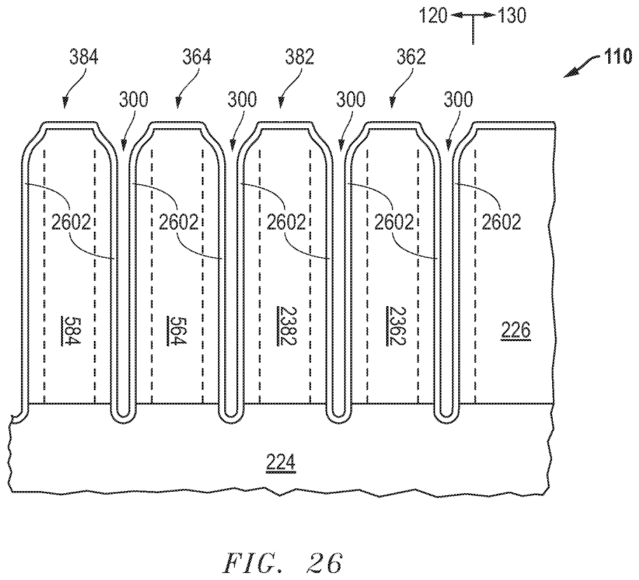

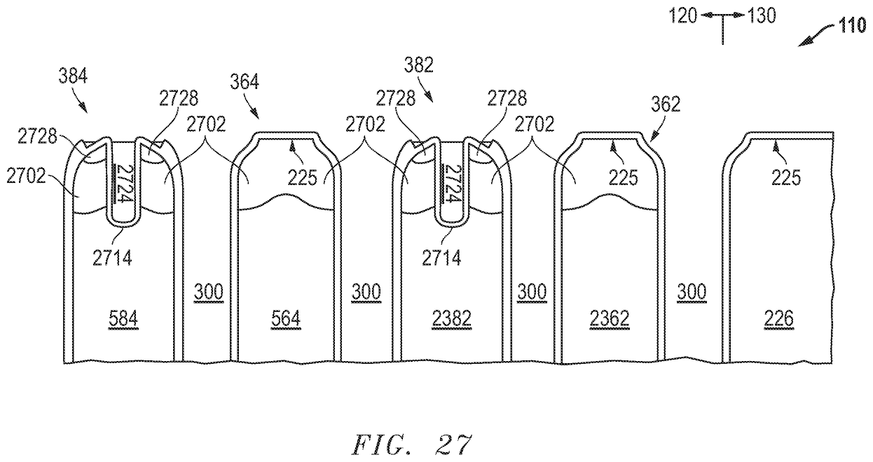

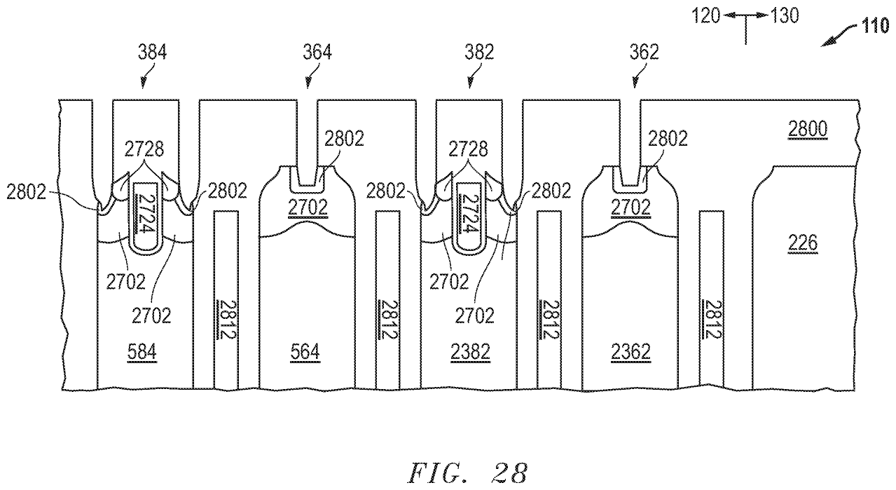

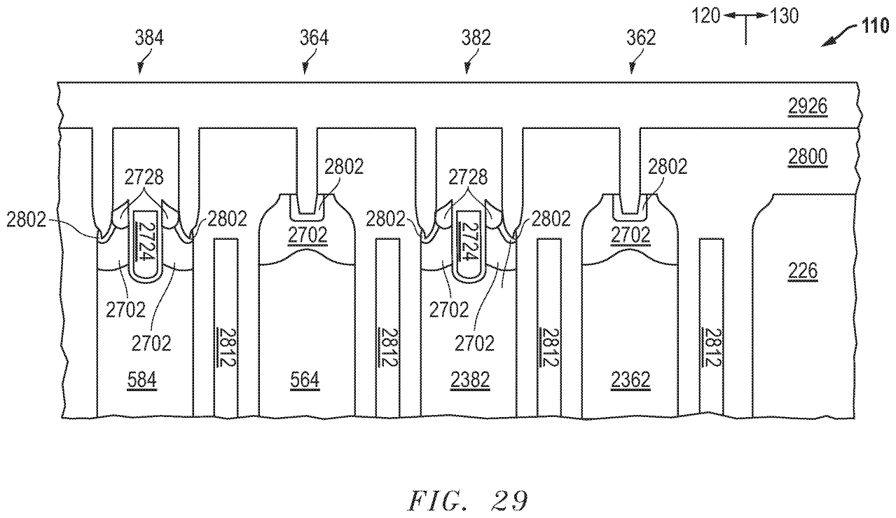

FIG. 28 includes the portion of the die 110 after forming an insulating layer 2800 within the trenches 300 (not labelled in FIG. 28) and over the pillars 362, 364, 382, and 384, patterning the insulating layer 2800 to define contact openings, and forming body contact regions 2802 within the p-well regions 2702. The insulating layer 2800 can include one or more films that include an oxide, a nitride, or an oxynitride. In an embodiment, an insulating film can be formed that seals the trenches 300 to define voids 2812. Another insulating film can be deposited and planarized. A further insulating film may be used as an etch-stop film or an antireflective film. After reading this specification, skilled artisans will be able to determine the number insulating films and their compositions and whether a separate planarization operation is needed.

The insulating layer 2800 is patterned to form the contact openings. The contact openings can have depths that extend into the p-well regions 2702 of the pillars 362, 364, 382, and 384. Within the pillars 382 and 384, the contact openings can contact the source regions 2728. The body contact regions 2802 are formed within the contact openings. The body contact regions 2802 can be heavily p-type doped to allow ohmic contacts to be subsequently-formed interconnects. Although not illustrated, the insulating layer 2800 can also be patterned to define contact openings that extend to the gate electrodes 2724 at locations not illustrated in FIG. 28. The patterning to define the contact openings to the gate electrodes 2724 can be performed during a separate operation as compared to patterning the insulating layer 2800 to define the contact openings for the body contact regions 2802. Further, the dopant operation described with respect to the body contact regions 2802 may or may not performed for the contact openings to the gate electrodes.

FIG. 29 includes the portion of the die 110 after forming a substantially complete electronic device. A conductive layer can be formed over the insulating layer 2800 and within the contact openings. The conductive layer can include one or more conductive films. When the conductive layer includes a plurality of films, an adhesion film or a barrier film can be deposited before a bulk conductive film. An antireflective film can be formed over the bulk conductive film and can include a metal nitride film. The conductive layer can have a thickness in a range from 1.1 microns to 6 microns. The conductive layer can be patterned to form the interconnect 2926 and an interconnect (not illustrated in FIG. 29) to the gate electrodes 2724. The interconnect 2926 may extend over part of the termination region 130 to act as a shield electrode to control the electrical field in the termination region 130. The interconnect 2926 can be a source terminal for the transistor, and the interconnect to the gate electrodes 2724 can be a gate terminal. If needed or desired, other interconnects may also be formed at this time. After an optional backgrind operation, backside metal can be formed along an exposed surface of the semiconductor base material 222. In an embodiment, the backside metal (not illustrated) can be plated onto or attached to the exposed surface of the semiconductor base material 222. In a particular embodiment, the backside metal can be a metal or a metal alloy. Exemplary materials can include at least 50 wt. % of Al, Ni, Cu, Au, or the like. The backside metal can be a drain terminal for the transistor.

Additional processing details regarding formation of the active region 120 after formation and initial doping of the pillars 362, 364, 382, and 384 may be found in U.S. application Ser. No. 16/141,761 filed Sep. 25, 2018, which is incorporated herein by reference in its entirety. Some of the dimensions as described within such application can be changed without deviating from the concepts as described in this specification.

Embodiments as described herein can help to reduce an electrical field near an edge of the active region near a termination region of a die. The reduced electrical field can allow the breakdown voltage to be governed by the design of cells within the interior of the active region as opposed to portions of the die that are adjacent to the boundary between the active and termination regions near a primary surface. The reduced electrical field can be achieved by having reduced net charge within pillars of the active region near the termination region, as opposed to pillars near the center of the active region. The reduced electrical field may also be achieved by doping pillars within the active region that are closer to the termination region with part, and not all, of a full dose used to dope corresponding interior pillars, by at least partly counter doping pillars within the active region that are closer to the termination region, or a combination of partial doses and counter doping.

Since an aspect of this disclosure pertains to the engineering of net charge in the active region near the termination region of a device, it can be applied to many different types of transistor structures. For instance, embodiments are illustrated with trench-type gates. Other embodiments can have planar-type gate electrodes. Furthermore, a deep trench structure with an insulating liner is illustrated separating the pillars. This deep trench structure may not be present in other embodiments. The pillars may be formed using a series of epitaxial growth operation (e.g., alternating a p-type epitaxial growth and an n-type epitaxial growth). Also, the temperature and duration of the thermal drive may be either increased or decreased, resulting in more or less uniform distribution of doping. Surface implants may be added of either conductivity type, with or without a mask, to modify surface conductivity properties without significantly altering the average doping concentration of the pillars. These various embodiments can be achieved without deviating from the concepts as described herein.

Many different designs are described herein. After reading this specification, skilled artisans will appreciate that many more designs can be used without deviating from the concepts as described herein. The designs can be integrated into an existing process flow without needing to add any further steps.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the embodiments as listed below.

Embodiment 1. An electronic device can include an active region including an array of pillars. The array of pillars can include a first pillar having a first net charge of a first charge type; a second pillar having a second net charge of a second net charge type opposite the first charge type; and interior pillars including alternating odd-numbered pillars having third net charges of the first charge type and even-numbered pillars having fourth net charges of the second charge type. The second pillar can be disposed between the first pillar and the interior pillars, and an absolute value of the first net charge or an absolute value of the second net charge is less than an absolute value of each of the third net charges.

Embodiment 2. The electronic device of Embodiment 1, wherein the second net charge is substantially the same as each of the fourth net charges.

Embodiment 3. The electronic device of Embodiment 1, wherein the absolute value of the second net charge is less than the absolute value of each of the third net charges.

Embodiment 4. The electronic device of Embodiment 3, wherein the second net charge is significantly less than each of the fourth net charges.

Embodiment 5. The electronic device of Embodiment 1, wherein the electronic device includes a die having a first side and a second side opposite the first side, the die includes the array of pillars, and the first pillar is a pillar within the array of pillars that is closest to the first side of the die. The array of pillars can further include a third pillar having substantially the first net charge of the first charge type and a fourth pillar having substantially the second net charge of the second charge type. The fourth pillar can be disposed between the third pillar and the interior pillars, and the third pillar can be a pillar within the array of pillars that is closest to the second side of the die.

Embodiment 6. The electronic device of Embodiment 1 can further include an insulating layer having an insulator charge of the second charge type, and a sum of a total first-type charge and a total second-type charge is no greater than 5%.

Embodiment 7. The electronic device of Embodiment 6, wherein the insulator charge is at least 5% of the total second-type charge.

Embodiment 8. An electronic device can include an active region including an array of pillars that include a first pillar, a second pillar, and a third pillar. The first pillar can include a first doped region extending along a majority of a first height of the first pillar, wherein the first doped region includes a first dopant at a first average dopant concentration. The second pillar can include a second doped region extending along a majority of a second height of the second pillar, wherein the second doped region includes a second dopant at a second average dopant concentration. The third pillar can include a third doped region extending along a majority of a third height of the third pillar, wherein the third doped region includes a third dopant having a first conductivity type, the third dopant is at a third average dopant concentration. The second pillar can be disposed between the first pillar and the third pillar, and the third average dopant concentration can be greater than the first average dopant concentration or the second average dopant concentration.

Embodiment 9. The electronic device of Embodiment 8, wherein the first average dopant concentration is significantly less than the third average dopant concentration.

Embodiment 10. The electronic device of Embodiment 8, wherein the second average dopant concentration is less than the third average dopant concentration.

Embodiment 11. The electronic device of Embodiment 10, wherein the array further includes:

a fourth pillar including a fourth doped region extending along a majority of a fourth height of the fourth pillar, wherein the fourth doped region includes a fourth dopant having a second conductivity type opposite the first conductivity type, wherein the fourth dopant is at a fourth average dopant concentration, and the fourth average dopant concentration is significantly greater than the second average dopant concentration.

Embodiment 12. The electronic device of Embodiment 8, wherein the first dopant has the first conductivity type, the second dopant has a second dopant type opposite the first conductivity type, and the first average dopant concentration is significantly less than the second average dopant concentration.

Embodiment 13. The electronic device of Embodiment 8, wherein the first dopant has the first conductivity type, the second dopant has a second dopant type opposite the first conductivity type, the first doped region further includes a fourth dopant having the second conductivity type, and the fourth dopant is at a fourth average dopant concentration that is significantly less than the first average dopant concentration.

Embodiment 14. The electronic device of Embodiment 8, wherein the first dopant has the first conductivity type, the second dopant has a second dopant type opposite the first conductivity type, the second doped region further includes a fourth dopant having the first conductivity type, and the fourth dopant is at a fourth average dopant concentration that is significantly less than the second average dopant concentration.

Embodiment 15. The electronic device of Embodiment 8, wherein the first dopant has the first conductivity type, the second dopant has a second dopant type opposite the first conductivity type, the first doped region further includes a fourth dopant having the second conductivity type, the fourth dopant is at a fourth average dopant concentration, and the second average dopant concentration is significantly less than the fourth average dopant concentration.

16. The electronic device of Embodiment 15, wherein the first average dopant concentration is substantially the same as the third average dopant concentration.

Embodiment 17. The electronic device of Embodiment 8, wherein the electronic device includes a die has a first side, the die includes the array of pillars, and the first pillar is an outermost pillar to the first side of the die.

Embodiment 18. The electronic device of Embodiment 8, wherein the first doped region or the second doped region is non-uniformly doped, and the third doped region is substantially uniformly doped.

Embodiment 19. An electronic device can include an active region include an array of pillars. The array of pillars can include an alternating pattern of p-type pillars having acceptor type dopant species and n-type pillars having donor type dopant species; and an insulating layer between adjacent pillars within the array of pillars. A negative charge can be associated with the acceptor type dopant species of the p-type pillars, a positive charge can be associated with the donor type dopant species of the n-type pillars and the insulating layer, and an absolute value of a net charge of the active region may be no more than 5% of the negative charge.

Embodiment 20. The electronic device of Embodiment 19, wherein the insulating layer is at least 5% of the positive charge.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electronic device comprising:
an active region including an array of pillars, wherein the array of pillars includes:
a first pillar having a first net charge of a first charge type;
a second pillar having a second net charge of a second net charge type opposite the first charge type; and
interior pillars including alternating odd-numbered pillars having third net charges of the first charge type and even-numbered pillars having fourth net charges of the second charge type,
wherein:
the second pillar is disposed between the first pillar and the interior pillars, and
an absolute value of the first net charge or an absolute value of the second net charge is less than an absolute value of each of the third net charges.

2. The electronic device of claim 1, wherein the second net charge is substantially the same as each of the fourth net charges.

3. The electronic device of claim 1, wherein the absolute value of the second net charge is less than the absolute value of each of the third net charges.

4. The electronic device of claim 3, wherein the second net charge is significantly less than each of the fourth net charges.

5. The electronic device of claim 1, wherein:
the electronic device includes a die having a first side and a second side opposite the first side,
the die includes the array of pillars,
the first pillar is a pillar within the array of pillars that is closest to the first side of the die, and
the array of pillars further comprises:
a third pillar having substantially the first net charge of the first charge type,
a fourth pillar having substantially the second net charge of the second charge type,
the fourth pillar is disposed between the third pillar and the interior pillars, and
the third pillar is a pillar within the array of pillars that is closest to the second side of the die.

6. The electronic device of claim 1, further comprising an insulating layer having an insulator charge of the second charge type, and a sum of a total first-type charge and a total second-type charge is no greater than 5%.

7. The electronic device of claim 6, wherein the insulator charge is at least 5% of the total second-type charge.

8. An electronic device comprising:
an active region including an array of pillars including:
a first pillar including a first doped region extending along a majority of a first height of the first pillar, wherein the first doped region includes a first dopant at a first average dopant concentration;
a second pillar including a second doped region extending along a majority of a second height of the second pillar, wherein the second doped region includes a second dopant at a second average dopant concentration; and
a third pillar including a third doped region extending along a majority of a third height of the third pillar, wherein the third doped region includes a third dopant having a first conductivity type, the third dopant is at a third average dopant concentration,
wherein:
the second pillar is disposed between the first pillar and the third pillar, and
the third average dopant concentration is greater than the first average dopant concentration or the second average dopant concentration.

9. The electronic device of claim 8, wherein the first average dopant concentration is significantly less than the third average dopant concentration.

10. The electronic device of claim 8, wherein the second average dopant concentration is less than the third average dopant concentration.

11. The electronic device of claim 10, wherein the array further comprises:
a fourth pillar including a fourth doped region extending along a majority of a fourth height of the fourth pillar, wherein the fourth doped region includes a fourth dopant having a second conductivity type opposite the first conductivity type, wherein the fourth dopant is at a fourth average dopant concentration, and the fourth average dopant concentration is significantly greater than the second average dopant concentration.

12. The electronic device of claim 8, wherein the first dopant has the first conductivity type, the second dopant has a second dopant type opposite the first conductivity type, and the first average dopant concentration is significantly less than the second average dopant concentration.

13. The electronic device of claim 8, wherein the first dopant has the first conductivity type, the second dopant has a second dopant type opposite the first conductivity type, the first doped region further includes a fourth dopant having the second conductivity type, and the fourth dopant is at a fourth average dopant concentration that is significantly less than the first average dopant concentration.

14. The electronic device of claim 8, wherein the first dopant has the first conductivity type, the second dopant has a second dopant type opposite the first conductivity type, the second doped region further includes a fourth dopant having the first conductivity type, and the fourth dopant is at a fourth average dopant concentration that is significantly less than the second average dopant concentration.

15. The electronic device of claim 8, wherein the first dopant has the first conductivity type, the second dopant has a second dopant type opposite the first conductivity type, the first doped region further includes a fourth dopant having the second conductivity type, the fourth dopant is at a fourth average dopant concentration, and the second average dopant concentration is significantly less than the fourth average dopant concentration.

16. The electronic device of claim 15, wherein the first average dopant concentration is substantially the same as the third average dopant concentration.

17. The electronic device of claim 8, wherein:
the electronic device includes a die having a first side,
the die includes the array of pillars, and
the first pillar is an outermost pillar to the first side of the die.

18. The electronic device of claim 8, wherein the first doped region or the second doped region is non-uniformly doped, and the third doped region is substantially uniformly doped.

19. An electronic device comprising:
an active region including:
an array of pillars, wherein the array of pillars includes an alternating pattern of p-type pillars having acceptor type dopant species and n-type pillars having donor type dopant species; and
an insulating layer between adjacent pillars within the array of pillars,
wherein:
a negative charge is associated with the acceptor type dopant species of the p-type pillars,
a positive charge is associated with the donor type dopant species of the n-type pillars and the insulating layer, and
an absolute value of a net charge of the active region is no more than 5% of the negative charge.

20. The electronic device of claim 19, wherein the insulating layer is at least 5% of the positive charge.
